(19) United States
(12) Patent Application Publication
(10) Pub. No.: US 2011/0164253 A1
(43) Pub. Date: Jul. 7, 2011

(54) METHOD OF MODIFYING A SUBSTRATE FOR DEPOSITION OF CHARGED PARTICLES THEREON

(76) Inventors: Xiaodong Zhou, Singapore (SG); Nan Zhang, Singapore (SG); Kai Yu Liu, Queensland (AU); Su Yin Oh, Singapore (SG); Jisheng Pan, Singapore (SG)

(21) Appl. No.: 12/737,626

(22) PCT Filed: Aug. 3, 2009
(86) PCT No.: PCT/SG2009/000270

§ 371 Date: Mar. 18, 2011

Related U.S. Application Data
(60) Provisional application No. 61/085,675, filed on Aug. 1, 2008.

(51) Int. Cl. G01N 21/55; C23C 14/34; C23C 16/44; B05D 1/36; C23C 14/48; B05D 1/06; B32B 5/16; B32B 3/00; B82Y 99/00

(52) U.S. Cl. 356/445; 204/192.1; 427/255.28; 427/402; 427/527; 427/475; 428/143; 216/24; 977/773

(57) ABSTRACT

A method of modifying a substrate for deposition of charged particles thereon, the method comprising the steps of: providing a substrate that is incapable of bonding to a polyelectrolyte coating that has a charge that is opposite to the charge of the particles that are to be deposited thereon; modifying the surface of the substrate to provide a layer of silicon thereon or therein; and coating the silicon layered surface of the substrate with the polyelectrolyte coating, the polyelectrolyte coating containing functional groups that are capable of forming bonds with said silicon layer and wherein said polyelectrolyte coating enables a substantially even distribution of said charged particles to be deposited thereon.

### TECHNICAL FIELD

The present invention generally relates to a method of modifying a substrate for deposition of charged particles thereon, a method of depositing charged particles on a substrate, and a method of making a substrate capable of producing Localized Surface Plasmon Resonance (LSPR). The present invention also relates to the substrate obtained by these methods.

### BACKGROUND

Localized surface plasmon resonance (LSPR) is a phenomenon to detect biological interfaces through frequency resonance of light photon and collective oscillation of conductive electrons in noble metal (such as gold (Au) and silver (Ag)) nanostructures. LSPR is measured from the absorption spectrum of the metal nanostructures, where peak of the spectrum will shift in accordance with binding of biological samples onto these nanostructures.

Nanostructures on substrates for use in LSPR can be fabricated using lithography methods, such as e-beam lithography and nanosphere lithography (NSL). NSL is an inexpensive high throughput process that employs self-assembled nanospheres as a lithographic mask during physical vapor deposition (PVD), and has emerged as a versatile patterning technique to create various nanostructures such as nano-dots and nano-rings. Designs in the form of two dimensional nano-crescents have also been reported.

Nanostructures on substrates fabricated using NSL can be used in LSPR, as LSPR does not require the nanostructures to be periodically arranged. The nanostructures on the substrate need to be identical in shape in order to narrow the absorption spectrum and enhance the LSPR signal obtained. The fabrication techniques used must also be capable of customizing the shapes of the nanostructures formed on the substrate in order to obtain the desired spectrum peak wavelength.

Typically, there are two ways which NSL is carried out. In the first approach, nanospheres are closely-packed such that they contact one another to form a one-layer hexagonal pattern. When metal is vertically evaporated on the nanospheres, triangular-like nanostructures of the metal are obtained in the interstices of these nanospheres after nanosphere dissolution. However, these patterns are defect free only within the range of 10˜100 μm. It has also been reported that attempts made to align the hexagon pattern in two to three layers after the first layer is arranged, results in an even smaller surface area that can be used. Hence, using this first approach, the area in which nanostructures is formed is limited, and this method also provides only limited varieties in the shapes of obtainable gold nanostructures.

In the second approach, nanospheres are first dispersed on the substrate. Oblique deposition and perpendicular etching of the metal film are then carried out to form metal nanostructures by utilizing the exposed areas under each nanosphere.

Despite the potential for NSL to be used in nanostructure fabrication for LSPR applications, conventional NSL such as the two methods described above still have the drawback of being capable of allowing the nanoparticles to be dispersed only over relatively small areas of a substrate (i.e. in the micrometer range). This is because the nanospheres tend to aggregate when larger areas are used. While not being bound by theory, it is believed that this is due to the surface energy causing the nanospheres to aggregate together. In addition, the dispersion of nanospheres over large areas is unrepeatable and difficult to control.

Another known technique to disperse nanospheres is to coat a layer of poly(diallyldimethylammonium chloride) (PDDA) on the silicon surface to introduce positive charges on the surface of the silicon. While most commercially purchased nanospheres are negatively charged, the electrostatic force between the nanospheres and PDDA helps to distribute the nanospheres evenly on the silicon substrate. However PDDA works only for pure silicon substrates. When PDDA is placed on a non-pure silicon substrate such as glass, which is predominantly composed of silica, the PDDA will not adhere to the glass but in fact will slip off from the glass. Hence, it is not feasible to place nanospheres on a silicon substrate covered with PDDA.

In LSPR applications, it is important to fabricate noble metal nanostructures on a light transparent substrate, such as glass or quartz, in a distributed arrangement on the surface of the substrate. Thus known NSL techniques are not suitable, or problematic, for preparing substrates for use in LSPR applications because the metal nanostructures are difficult to arrange in an even distribution on the substrate surface or, if PDDA is used, the PDDA can not adhere to the glass or quartz substrate.

There is a need to provide a method of preparing a substrate for dispersion of particles thereon, that overcomes, or at least ameliorates, one or more of the disadvantages described above.

There is a need to provide a method of preparing a light transparent substrate, such as glass or quartz, such that nanospheres can be evenly distributed over a large area of the substrate.

There is also a need to provide a method of dispersing particles evenly over a large area of a substrate as well as a substrate that is capable of allowing particles to be evenly distributed throughout a large area on its surface and is suitable for use in LSPR applications.

### SUMMARY

According to a first aspect, there is provided a method of modifying a substrate for deposition of charged particles thereon, the method comprising the steps of:

providing a substrate that is incapable of readily adhering to a polyelectrolyte coating that has a charge that is opposite to the charge of the particles that are to be deposited thereon;

modifying the surface of the substrate to provide a layer of silicon thereon or therein; and

coating the silicon layered surface of the substrate with the polyelectrolyte coating, the polyelectrolyte coating containing functional groups that are capable of forming bonds with said silicon layer and wherein said polyelectrolyte coating enables a substantially even distribution of said charged particles to be deposited thereon. The layer of silicon on or within the surface of the substrate may be comprised entirely of pure silicon or may be rich in silicon. In one embodiment, the modifying step comprises providing a silicon rich layer on or within the surface of the substrate.

Advantageously, the method allows a substrate to be prepared such that when the particles are dispersed on the prepared substrate, there is relatively more even distribution over a larger area of the prepared substrate as compared to dispersing particles on a same starting substrate which is not prepared using the above-mentioned method. Due to the difference in electrical polarity of the prepared surface and the particles, the particles are also capable of being adhered to the prepared surface more easily due to the presence of attractive electrostatic forces between the charged particles and the polyelectrolyte coating.

In one embodiment, the particles may be capable of being dispersed onto the substrate such that the dispersed particles are substantially evenly distributed over at least 80% of the area of said surface. Advantageously, this maximizes that use of the surface area of the substrate and allows large substrates having a substantially evenly distribution of particles to be fabricated relatively easily. There is also comparatively reduced amount of unusable areas of the substrates when the present method is used due to the even distribution of particles thereon. More advantageously, because large substrates having evenly distributed particles can be fabricated using the above mentioned method, even if smaller substrates are eventually desired, these large substrates can be further diced into smaller substrates of the desired sizes for multiple uses. This method reduces the processing time required for fabrication of smaller substrates and is more efficient than methods which have to repeatedly disperse the particles on each of the smaller substrates.

The particles used herein may be substantially spherical in shape so that nanostructures eventually formed on the prepared substrate may be advantageously curvilinear structures.

In one embodiment, the substrate is optically transparent. The optically transparent substrate may have a light transmission of from 70% to 100%. Advantageously, the prepared transparent substrate would be suitable for use in LSPR applications, which typically requires transmission of the light from a light source through the substrate containing nanostructures thereon, to a light detector, and hence an optically transparent substrate.

In one embodiment, the step of modifying the substrate comprises depositing a layer of silicon onto the surface of the substrate. The depositing step may be carried out using at least one of low pressure chemical vapor deposition (LPCVD) and sputtering. In another embodiment, the step of modifying the substrate comprises implanting silicon ions into the substrate. In yet another embodiment, the step of modifying the substrate comprises implanting non-silicon ions into the substrate. In still yet another embodiment, the step of modifying the substrate comprises sputtering non-silicon ions onto the surface of the substrate. The step of sputtering may be carried out using X-ray photoelectron spectroscopy.

Advantageously, these methods ensure the presentation of silicon atoms at a surface of the substrate so that in the subsequent step, the polyelectrolyte or precursor thereof that is to be coated on the substrate, can adhere more effectively to the substrate.

In one embodiment, the polelectrolyte used to coat the substrate surface is poly(diallyldimethylammonium chloride) (PDDA). In another embodiment, the precursor used to coat the substrate surface is a triple layer precursor film of PDDA/poly(sodium 4-styrenesulfonate)/aluminium chloride hydroxide. Advantageously, when the substrate is eventually coated with PDDA, the entire coated substrate surface is capable of dispersing particles thereon over a large surface area as well as ensuring that the dispersed particles adhere securely onto the surface of the substrate and are not easily dislodged, such as by being washed away.

The coated surface may be positively charged. This is beneficial as commercially available nanospheres (that are to be dispersed onto the surface) are typically negatively charged. However, it should be noted that the coated surface may be negatively charged if the charged particles are positively charged.

In one embodiment, the particles used for dispersion over the surface of the substrate are in a suspension. Advantageously, the prepared substrate ensures that the density of dispersed particles on the surface is independent of the concentration of particles in the suspension for a fixed total number of particles. This ensures that substrates containing a desired density of dispersed particles are easily and consistently reproducible. Hence, the desired density of particles on the substrate can be controlled according to the users' requirements. This is especially advantageous when the substrates have to be used in several experiments, all of which require the density of distributed particles to be fixed.

The particles used for distribution on the prepared surface may have average diameters in the range of from nm to 1500 nm. This advantageously ensures that structures that are subsequently further produced on the substrate are nano-sized or micro-sized. This beneficially allows the substrate together with the nano-sized or micro-sized structures thereon to be capable of producing LSPR.

In a second aspect, there is provided a method of depositing charged particles on a substrate, the method comprising the steps of:

providing a substrate that is incapable of readily adhering to a polyelectrolyte coating that has a charge that is opposite to the charge of the particles that are to be deposited thereon;

modifying the surface of the substrate to provide a layer of silicon thereon or therein;

coating the silicon layered surface of the substrate with the polyelectrolyte coating, the polyelectrolyte coating containing functional groups that are capable of forming bonds with said silicon layer; and

depositing a suspension of the charged particles over the coated surface, wherein said polyelectrolyte coating enables a substantially even distribution of said charged particles deposited thereon.

Advantageously, the method produces substrates that are capable of being used in LSPR applications.

According to a third aspect, there is provided a substrate that is incapable of readily adhering to a polyelectrolyte coating comprising:
a layer of silicon on or within said substrate that has bonded with functional groups within the polyelectrolyte coating; and
charged particles substantially evenly distributed on said substrate.

According to a fourth aspect, there is provided a localized surface plasmon resonance system comprising:

a source of light;

a sensor chip comprising a substrate having a layer of silicon on or within said substrate that has bonded with functional groups within a polyelectrolyte coating and nano-sized reflective particles substantially evenly distributed on said substrate, said nano-sized reflective particles being disposed along an optical path for the transmission of a light beam from the light source to produce a localized surface plasmon resonance signal; and

a detector disposed along the optical path for detecting the localized surface plasmon resonance signal emitted by said reflective particles.

According to a fifth aspect, there is provided the use of the substrate as defined above for Localized Surface Plasmon Resonance or plasmonics signal detection applications.

### DEFINITIONS

The following words and terms used herein shall have the meaning indicated:

The term “optically transparent” refers to any substance that allows light to easily pass therethrough such that objects placed on one side of the substance can be viewed with the naked eye through the opposite side of the substance.

The term “nano-sized” is to be interpreted broadly to relate to an average particle size of less than about 1000 nm, particularly between about 50 nm to about 1000 nm, more particularly less than about 500 nm. The particle size may refer to the diameter of the particles where they are substantially spherical. The particles may be non-spherical and the particle size range may refer to the equivalent diameter of the particles relative to spherical particles.

The term “micro-sized” is to be interpreted broadly to, unless specified, relate to an average particle size of between about 1 μm to about 100 μm. The particle size may refer to the diameter of the particles where they are substantially spherical. The particles may be non-spherical and the particle size range may refer to the equivalent diameter of the particles relative to spherical particles.

The term “nanostructures” as used herein is to be interpreted broadly to include free-standing or isolated three dimensional structures from the surface of the substrate which have at least two dimensions that are less than about 1 μm, more typically less than 500 nm.

The terms “bond”, “bonds”, “bonding”, “bonded” and grammatical variants thereof as used herein are to be interpreted broadly to include physical and chemical interactions and are not limited, but may include, electrostatic interaction, ionic bonds, covalent bonds, hydrogen bonds, hydrophobic interactions, hydrophilic interactions and dipole-dipole interaction.

The term “incapable” as used herein is not intended to represent “closed” or “absolute” language such that it also includes “partially capable”. Likewise, the phrase “substrate incapable of readily adhering to a electrolyte coating” is intended to include not only the situation where the substrate is not able to completely interact or adhere directly to the polyelectrolyte coating, but also includes a situation where the substrate only partially interacts with the polyelectrolyte coating.

The term “modifying” when referring to the surface of a substrate is to be interpreted broadly to refer to the step involved in order to alter the surface properties of the substrate.

The term “silicon rich layer” and grammatical variants thereof, when used in conjunction with a surface or when used to describe a surface is to be interpreted broadly to refer to that part of the surface layer which has been modified in order to increase the amount of silicon atoms and/or ions as compared to the same surface but which had not been modified. Accordingly, a surface that has been modified to have a silicon rich layer thereon or therein includes one that has been modified to have an increased amount of silicon ions and/or atoms deposited on the surface and also includes one that has been modified to release silicon ions and/or atoms to the existing surface such that an amount of silicon ions and/or atoms is present on or within the surface. For example, when a glass substrate (SiO₂) is being modified via implantation to have a silicon rich layer, silicon atoms/ions may be released from SiO₂, increasing the amount of silicon atoms and/or ions on or within the surface.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### DETAILED DISCLOSURE OF EMBODIMENTS

Exemplary, non-limiting embodiments of a method of modifying a substrate for deposition of charged particles thereon, a method of depositing charged particles on a substrate, a method for making a substrate capable of producing Localized Surface Plasmon Resonance and a substrate for use in localized surface plasmon resonance will now be disclosed.

The method of modifying a substrate for deposition of charged particles thereon comprises the steps of providing a substrate that is incapable of bonding to a polyelectrolyte coating that has a charge that is opposite to the charge of the particles that are to be deposited thereon; modifying the surface of the substrate to provide a layer of silicon thereon or therein; and coating the silicon layered surface of the substrate with the polyelectrolyte coating, the polyelectrolyte coating containing functional groups that are capable of forming bonds with said silicon layer and wherein said polyelectrolyte coating enables a substantially even distribution of said charged particles to be deposited thereon. The layer of silicon may be a very thin layer of less than about 30 nm, less than about 20 nm or less than about 10 nm.

In one embodiment, the polyelectrolyte is a polycation. The polycation may comprise at least one of quaternary ammonium groups and amino groups. In one embodiment, the quaternary ammonium groups and amino groups of said polyelectrolyte coating may be selected from the group consisting of a linear or branched poly(ethylene imine) (PEI), poly(allylamine hydrochloride) (PAH), poly(diallyldimethylammonium chloride) (PDDA), polyvinyl pyridine (PVP), polylysine and precursors thereof. In another embodiment, the precursor used to coat the substrate surface is a triple layer precursor film of diallyldimethylammonium chloride/(sodium 4-styrenesulfonate)/aluminium chloride hydroxide, in which the monomers may polymerize. Preferably, after the substrate is coated with the polyelectrolye or precursor, the coated surface becomes positively charged.

In one embodiment, the charged particles are capable of being dispersed onto the substrate such that the dispersed particles are substantially evenly distributed over at least about 80%, over at least about 85%, over at least about 90% or over at least about 95% of the area of said surface.

The particles may be substantially regular or irregular in shape. The particles may be micro-sized or nano-sized. The cross-section of the particles may be substantially circular, triangular, rectangular, rhombic, ellipsoid or square. In one embodiment, when the particles have a substantially circular cross-section, the diameter of the nanostructures may range from about nanometers to about 1500 nanometers, from about 20 nanometers to about 1000 nanometers, from about 30 nanometers to about 800 nanometers, from about 40 nanometers to about 500 nanometers, from about 50 nanometers to about 400 nanometers, from about 100 nanometers to about 300 nanometers, from about 100 nanometers to about 200 nanometers, from about 200 nanometers to about 500 nanometers and from about 300 nanometers to about 500 nanometers.

In another embodiment, when the particles are rectangular or square-shaped in cross-section, the lengths and breadth of the rectangle or square cross-sections may range from about 10 nanometers to about 1500 nanometers, from about 20 nanometers to about 1000 nanometers, from about 30 nanometers to about 800 nanometers, from about 40 nanometers to about 500 nanometers, from about 50 nanometers to about 400 nanometers, from about 100 nanometers to about 300 nanometers, from about 100 nanometers to about 200 nanometers, from about 200 nanometers to about 500 nanometers and from about 300 nanometers to about 500 nanometers.

In one embodiment, the particle is selected from the group consisting of disks, cubes, cylinders and spheres. Preferably, the particles are substantially spherical in shape, more preferably nanospheres. The arrangement of the particles on the substrate may be random, patterned, periodic or ordered. In one embodiment, the particles are at least one of polystyrene particles, latex particles, silica particles and quartz particles.

In one embodiment, the substrate disclosed herein is optically transparent. The optically transparent substrate may have a light transmission of from about 70% to about 100%, from about 80% to about 100%, from about 90% to about 100% or from about 95% to about 100%.

The substrate may be selected from the group consisting of glass, silicon dioxide, silicon, silicon nitride, quartz, any other ceramics, Poly(methyl methacrylate) PMMA, polycarbonate, Poly(Ethylene-co-Ethyl Acrylate) (PEEA), Polydimethysiloxane (PDMS), silica, polymer, plastic and mixtures thereof. Hence, the substrate may, in some embodiments, contain silicon elements bonded to another element (i.e. such as silica SiO₂).

In one embodiment, the step of modifying the substrate comprises depositing a layer of silicon onto the surface of the substrate. The depositing step may be carried out using at least one of low pressure chemical vapor deposition (LPCVD) and sputtering. The deposition or sputtering step may be carried out on one or both sides of the substrate surface. The silicon deposited on the surface of the substrate may be at least one of polysilicon and amorphous silicon. In one embodiment, the silicon used possesses a refractive index in the range of about 4 to 6. The silicon used may also be chosen based on the desired extinction coefficient to absorb light, which in turn depends on the optical wavelength and the deposition temperature and method.

In another embodiment, the step of modifying the substrate comprises implanting silicon ions into the substrate. Advantageously, implanting silicon ions into the substrate reduces optical transmission loss as compared to when a silicon layer is deposited on the substrate. The ions may be implanted at a dosage of from about 1 E¹¹/cm² to about 1 E¹⁶/cm², from about 1 E¹²/cm² to about 1 E¹⁵/cm², from about 1 E¹³/cm² to about 1 E¹⁴/cm² or from about 1.5 E¹³/cm² to about 0.5 E¹⁴/cm².

In yet another embodiment, the step of modifying the substrate comprises implanting non-silicon ions into the substrate. The non-silicon ions may be selected from the group consisting of arsenic, boron and argon. While not being bound by theory, it is believed that the implanted ions strike the surface, damage lattice and break the Si—O bonds present within the Si—O containing substrate. Consequently, oxygen escapes out of the surface, and silicon is left on the substrate surface. The ions may be implanted at a dosage of from about 1 E¹¹/cm² to about 1 E¹⁶/cm², from about 1 E¹²/cm² to about 1 E¹⁵/cm², from about 1 E¹³/cm² to about 1 E¹⁴/cm² or from about 1.5 E¹³/cm² to about 0.5 E¹⁴/cm².

In still yet another embodiment, the step of modifying the substrate comprises sputtering non-silicon ions onto the surface of the substrate. The step of sputtering may be carried out using X-ray photoelectron spectroscopy and the non-silicon ions may be argon ions or any other inert gas ions such as xenon ions.

Preferably, argon sputtering is used. The ions may be sputtered at a dosage of from about 1 E¹³/cm² to about 1 E¹⁶/cm², from about 1 E¹⁴/cm² to about 1 E¹⁵/cm² or from about 1.5 E¹⁴/cm² to about 0.5 E¹⁵/cm². The ions are sputtered at a sputtering energy of from about 0.5 keV to about 5 keV, from about 1 keV to about 4.5 keV, from about 1.5 keV to about 4 keV, from about 2 keV to about 3.5 keV or from about 2.5 keV to about 3 keV.

In one embodiment, the particles are in a suspension before being dispersed onto the substrate. The present disclosed method may be capable of ensuring that the density of dispersed particles on the surface is independent of the concentration of particles in the suspension for a fixed total number of particles.

The method of depositing charged particles on a substrate comprises the steps of providing a substrate that is incapable of bonding to a polyelectrolyte coating that has a charge that is opposite to the charge of the particles that are to be deposited thereon; modifying the surface of the substrate to provide a layer of silicon thereon or therein; coating the silicon layered surface of the substrate with the polyelectrolyte coating, the polyelectrolyte coating containing functional groups that are capable of forming bonds with said silicon layer; and depositing a suspension of the charged particles over the coated surface, wherein said polyelectrolyte coating enables a substantially even distribution of said charged particles deposited thereon. In one embodiment, the method further comprises the step of depositing metals on said surface to form nanostructures thereon.

The method of making a substrate capable of producing Localized Surface Plasmon Resonance comprises providing a substrate that is incapable of bonding to a polyelectrolyte coating; modifying the surface of the substrate to provide a layer of silicon thereon or therein; coating the silicon layered surface of the substrate with the polyelectrolyte coating, the polyelectrolyte coating containing functional groups that are capable of forming bonds with said silicon layer and wherein said polyelectrolyte coating enables a substantially even distribution of said charged particles deposited thereon; depositing a suspension of charged particles over the coated surface, said particles having a charge that is opposite to the charge of the polyelectrolyte coating, depositing metals on said particle-containing surface; and etching the deposited metals to form nanostructures on said substrate.

The metals disclosed herein may be selected from the group consisting of Group IB, Group VIB, Group VIIIB, Group IVA, Group IVB, Group IIB and Group IIIA of the Periodic Table of Elements, as well as their alloys and combinations thereof. In one embodiment, the metal may be selected from the group consisting of aluminum, cobalt, copper, gold, indium, molybdenum, nickel, palladium, platinum, silver, tin, titanium, tungsten, zinc and combinations thereof. In one embodiment, the metal is a noble metal, such as gold.

The step of depositing metals on the surface may be carried out by thermal evaporation. The deposited metal may also be further etched to form the desired nanostructure. In one embodiment, the nanostructures eventually formed are at least one of nanorings, nanodots and nanocrescents.

In one embodiment, the substrate disclosed herein comprises a layer of silicon on or within said substrate; a layer of a polyelectrolyte coating bonded to said silicon layer, said polyelectrolyte coating containing functional groups capable of forming bonds with said silicon layer; and charged particles substantially evenly distributed on said substrate.

In one embodiment, the substrate is a substrate obtained for the methods disclosed above. The dispersed particles may be substantially evenly distributed over at least about 80%, over at least about 85%, over at least about 90% or over at least about 95% of the area of said surface.

The substrate disclosed herein may be used for Localized Surface Plasmon Resonance, plasmonics signal detection applications or any applications that require a light transparent substrate containing well dispersed particles over a large area of the substrate.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1a is the optical transmission (vertical axis) of a 500 μm thick glass wafer with amorphous silicon deposited on both sides, with the thickness of amorphous silicon varying from 0.5 to 30 nm (horizontal axis).

FIG. 1b is the optical transmission (vertical axis) of a 500 μm thick glass wafer with amorphous silicon deposited on one side, with the thickness of amorphous silicon varying from 5 to 100 nm (horizontal axis).

FIG. 1c is the optical spectra at varying wavelengths of 300 to 900 nm of two 500 μm thick glass wafers with amorphous silicon deposited on both sides (thickness of 5 nm and 30 nm).

FIG. 1d is the optical spectra at varying wavelengths of 300 to 900 nm of two 500 μm thick glass wafers with amorphous silicon deposited on one side (thickness of 5 nm and 100 nm).

FIG. 2 is the UV-vis spectral measurements of an unmodified glass substrate, of a glass substrate modified via amorphous silicon deposition on both sides and of a glass substrate modified by silicon ion implantation.

FIG. 3 is a graph showing the transmission of the various glass substrates after modification.

FIG. 4a is an AFM image of unmodified glass substrate. FIG. 4b is an AFM image of a glass substrate coated on one side with amorphous silicon of 100 nm thickness (or from Example 1.1). FIG. 4c is an AFM image of a glass substrate coated on both sides with amorphous silicon of 30 nm thickness (or from Example 1.1). FIG. 4d is an AFM image of a glass substrate modified via silicon ion implantation (or from Example 1.2). FIG. 4e is an AFM image of a glass substrate modified via arsenic ion implantation (or from Example 1.3). FIG. 4f is an AFM image of a glass substrate modified via boron ion implantation (or from Example 1.3). FIG. 4g is an AFM image of a glass substrate modified via argon ion implantation (or from Example 1.3). FIG. 4h is an AFM image of a glass substrate modified by argon sputtering in XPS (or from Example 1.4).

FIG. 5a is a SEM image obtained at 2,500× magnification of the nanospheres dispersed on a glass substrate with amorphous silicon deposition followed by PDDA treatment. FIG. 5b is the magnified image of FIG. 5a obtained at 23,000× magnification.

FIG. 6a is a SEM image obtained at 2,500× magnification of the nanospheres dispersed on a glass substrate implanted with silicon ions followed by PDDA treatment. FIG. 6b is the magnified image of FIG. 6a obtained at 23,000× magnification.

FIG. 7a is a SEM image obtained at 10,000× magnification of the nanospheres dispersed on a glass substrate implanted with arsenic ions followed by PDDA treatment. FIG. 7b is the magnified image of FIG. 7a obtained at 23,000× magnification. FIG. 7c is another SEM image obtained at 5,000× magnification of the nanospheres dispersed on a glass substrate implanted with arsenic ions followed by PDDA treatment. FIG. 7d is the magnified image of FIG. 7c obtained at 10,000× magnification.

FIG. 8a is a SEM image obtained at 5,000× magnification of the nanospheres dispersed on a glass substrate implanted with boron ions followed by PDDA treatment. FIG. 8b is the magnified image of FIG. 8a obtained at 30,000× magnification. FIG. 8c is another SEM image obtained at 3,000× magnification of the nanospheres dispersed on a glass substrate implanted with boron ions followed by PDDA treatment. FIG. 8d is the magnified image of FIG. 8c obtained at 10,000× magnification.

FIG. 9a is a SEM image obtained at 10,000× magnification of the nanospheres dispersed on a glass substrate implanted with argon ions followed by PDDA treatment. FIG. 9b is the magnified image of FIG. 9a obtained at 30,000× magnification.

FIG. 10a is a SEM image obtained at 10,000× magnification of the nanospheres dispersed on a glass substrate sputtered with argon in a XPSS machine followed by PDDA treatment. FIG. 10b is the magnified image of FIG. 10a obtained at 30,000× magnification.

FIG. 11a is a SEM image obtained at 1,900× magnification of the nanospheres dispersed on an unmodified glass substrate without PDDA treatment. FIG. 11b is the magnified image of FIG. 11a obtained at 15,000× magnification.

FIG. 12 is a LSPR spectra of the gold nanostructures on a modified, PDDA treated glass substrate in various media of air, water and 50 wt % glocyrol.

FIG. 13 is an image from a dark field microscope showing the LSPR emission of gold nanostructures on a modified, PDDA treated glass substrate.

FIG. 14a is a SEM image obtained at 1,000× magnification of nanospheres dispersed on a SiO₂ surface without PDDA treatment. FIG. 14b is the magnified image of FIG. 14a obtained at 10,000× magnification.

FIG. 15a is a SEM image obtained at 1,000× magnification of nanospheres dispersed on a PMMA plastic plate treated with PDDA. FIG. 15b is the magnified image of FIG. 15a obtained at 15,000× magnification.

FIG. 16a is a SEM image obtained at 3,000× magnification of nanospheres dispersed on a SiO₂ surface treated with PDDA. FIG. 16b is the magnified image of FIG. 16a obtained at 15,000× magnification.

FIG. 17a is a SEM image obtained at 3,000× magnification of nanospheres dispersed on a titanium surface treated with PDDA. FIG. 17b is the magnified image of FIG. 17a obtained at 15,000× magnification.

### EXAMPLES

Non-limiting examples of the invention will be further described in greater detail by reference to specific Examples, which should not be construed as in any way limiting the scope of the invention.

### Example 1

### Preparation of Substrate

In this Example, four methods to modify the substrate before the coating step were carried out. The first method (shown in Example 1.1) involved the sputtering/deposition of silicon on a substrate. The second method (shown in Example 1.2) involved the implantation of silicon into a substrate surface. The third method (shown in Example 1.3) involved the implantation of non-silicon ions into a substrate. The fourth method (shown in Example 1.4) involved the sputtering of argon onto the surface of a substrate in X-ray photoelectron spectroscopy (XPS).

### Example 1.1

### Sputtering/Deposition of Silicon on a Substrate

In this example, two samples were prepared. Before sputtering/deposition, the substrates in the form of glass wafers were cleaned using H₂SO₄/H₂O₉ at a ratio of 4:1 at a temperature of 90° C. before deposition. The first sample was prepared by depositing amorphous silicon on both sides of a glass substrate having a thickness of 500 μm using low-pressure chemical vapour deposition (LPCVD). The second sample was prepared by depositing amorphous silicon on one side of a glass wafer using LPCVD. Amorphous silicon was deposited on the glass wafer at a temperature of 550° C. and at a pressure of 300 mTorr. The gas flow of SiH₄ was 100 SCCM.

The resultant substrates were diced into 2 cm×2 cm pieces for experimental use.

In order to determine whether one side or both sides of the substrate should be coated with the amorphous silicon, optical transmissions were simulated by optical transmission theory, and the optical transmission for experimental samples were tested using an Ocean Optics spectrometer.

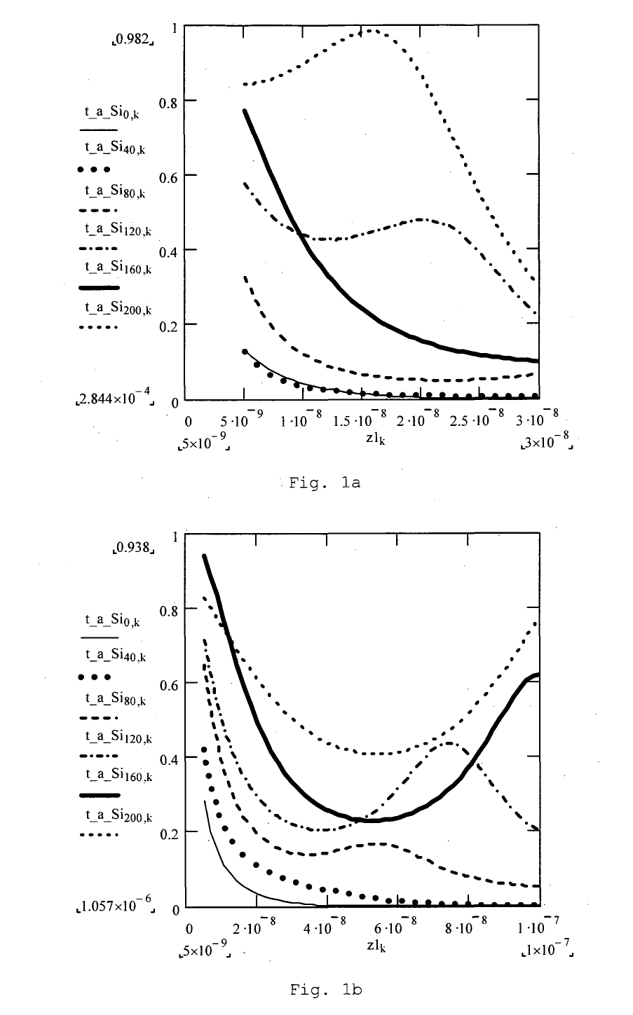

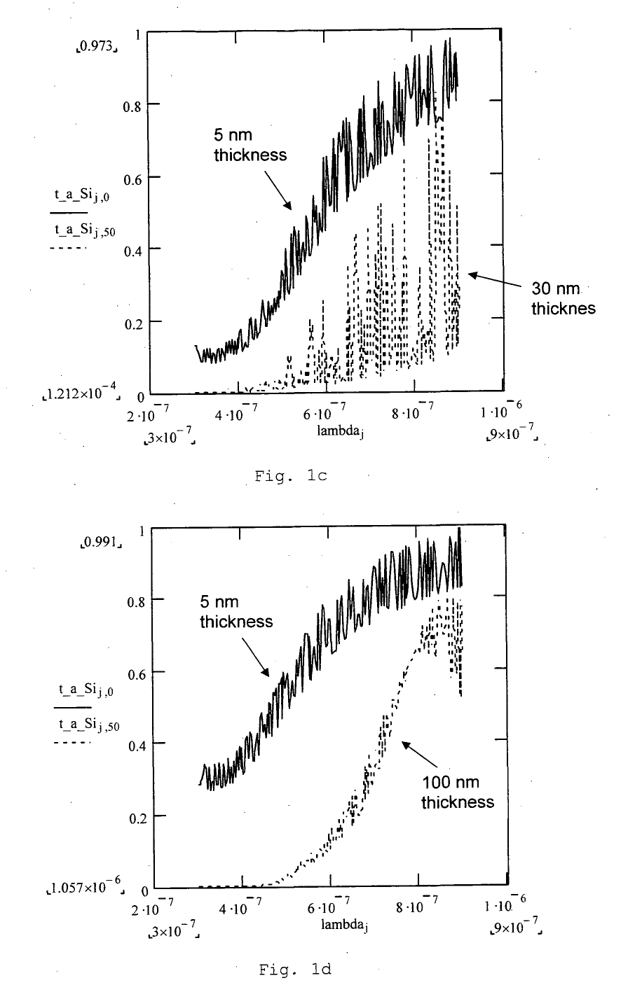

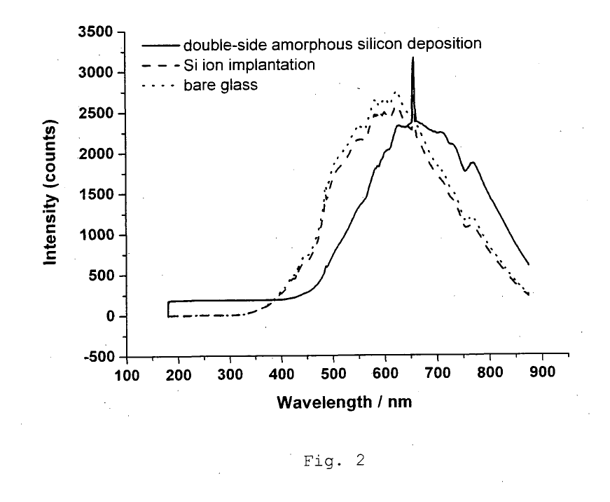

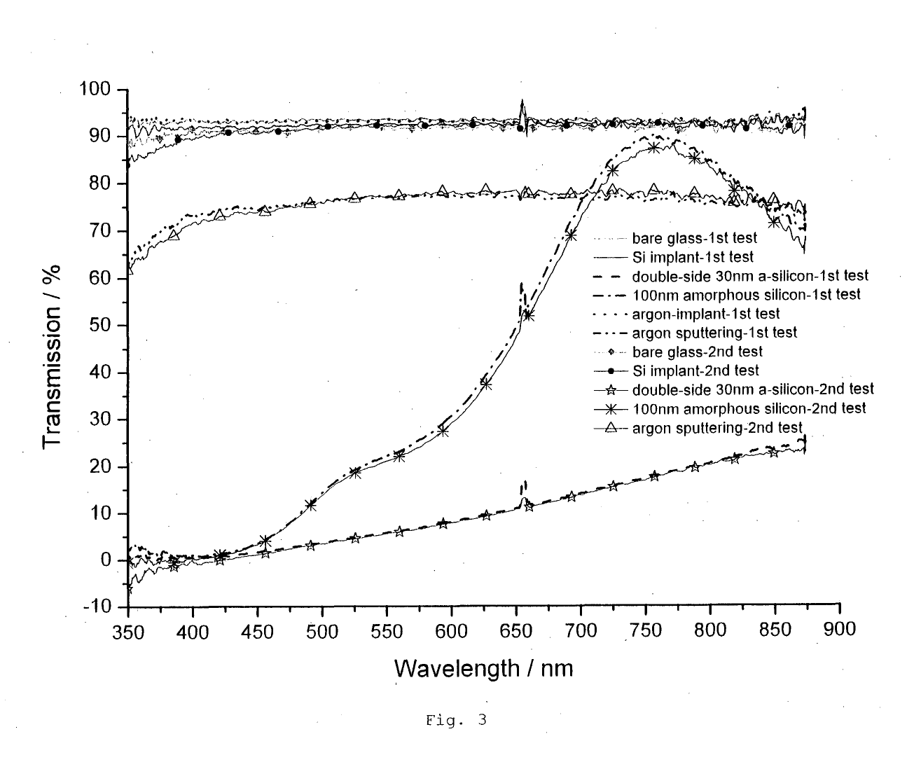

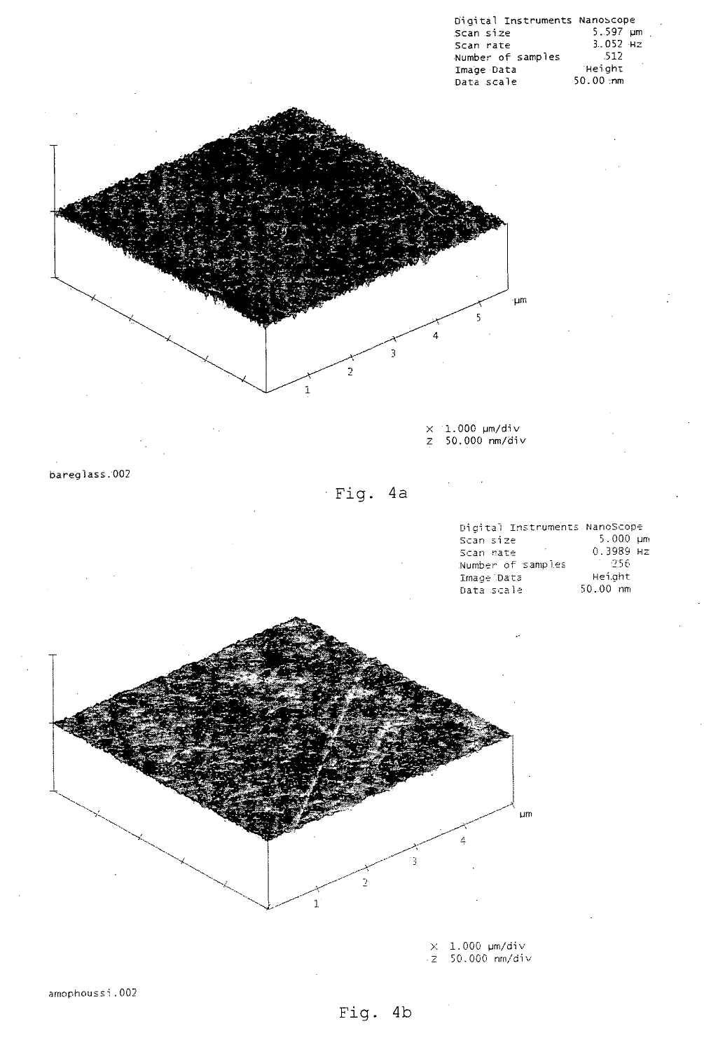

Optical transmission is a function of optical wavelength and thickness of amorphous silicon on the glass substrate. Varying wavelengths of 300 nm, 420 nm, 540 nm, 660 nm, 780 nm and 900 nm were simulated on the first sample when the thickness of the amorphous silicon was varied from 5 nm, 10 nm, 15 nm, 20 nm, 25 nm and 30 nm. The result of this optical transmission test for the first sample is shown in FIG. 1a. Varying wavelengths of 300 nm, 420 nm, 540 nm, 660 nm, 780 nm and 900 nm were simulated on the second sample when the thickness of the amorphous silicon was varied from 5 nm, 20 nm, 40 nm, 60 nm, 80 nm and 100 nm. The result of this optical transmission test for the second sample is shown in FIG. 1b. For FIG. 1a and FIG. 1b, the refractive indices and extinction coefficients of amorphous silicon at various wavelengths are taken from standard material data. Curves with suffixes of Si_{0,k}, Si_{40,k}, Si_{80,k}, Si_{120,k}, Si_{160,k}, and Si_{200,k} represent wavelengths of 300, 420, 540, 660, 780, and 900 nm, respectively.

As seen from FIG. 1a and FIG. 1b, amorphous silicon has a much higher extinction coefficient at a lower wavelength than at a longer wavelength. It can be seen that within the wavelength range of 300 nm to 900 nm, when the thickness of amorphous silicon is only 5 nm, the first sample exhibits a minimum optical transmission of only 0.127, while that of the second sample is 0.284, which is more than two times that of the first sample.

The transmission spectra of the first sample and second sample were calculated and presented as FIG. 1c and FIG. 1d, respectively. In FIG. 1c, when the wavelength varied from 300 to 900 nm, the transmissions varied from 0.082 to about 0.973 when the thickness of amorphous silicon was 5 nm and varied from 1.212×10⁻⁴ to about 0.833 when the thickness of amorphous silicon was 30 nm. In FIG. 1d, when the wavelength varied from 300 to 900 nm, the transmissions varied from 0.267 to about 0.991 when the thickness of amorphous silicon was 5 nm and varied from 1.057×10⁻⁶ to about 0.799 when the thickness of amorphous silicon was 100 nm. Hence, these optical simulation results suggest that the optimal silicon layer should be as thin as possible and that only one side of the glass substrate should be sputtered or deposited with amorphous silicon.

### Example 1.2

### Implantation of Silicon into a Substrate Surface

Three samples were fabricated in this example. The implantation energy for all three samples was fixed at 5 keV. Silicon dosages used are:

a) Sample 1: 1 E¹³/cm²;

b) Sample 2: 1 E¹⁵/cm²,

c) Sample 3: 1 E¹⁴/cm².

The substrate used in this Example is the same as the glass wafer used in Example 1.1. The glass wafer was treated in the same manner as that in Example 1.1 before silicon implantation.

The equipment used to implant the silicon ions into the glass wafers was the Varian ion implanter, using SiF₄ as the ion source.

It was found that dosage of the silicon ions is not important for the dispersion of the nanospheres as all of these silicon dosages generated good results. It was noted that there is a 100 times difference in dosage for Sample 1 and 2, while the 2 samples have similar results for nanosphere dispersion. Hence, the dosage used for Sample 3 was selected for the remaining examples. The average thickness of the silicon-rich surface layer was about 30 nm for all three samples.

One benefit of using silicon implantation as compared to deposition of silicon using LPCVD (as shown in Example 1.1) is that the glass substrate was totally transparent with no observable optical loss when silicon implantation was used. This is in comparison to the glass substrate from Example 1.1 as the thick amorphous silicon layer deposited using LPCVD made the glass surface to appear dark and shiny.

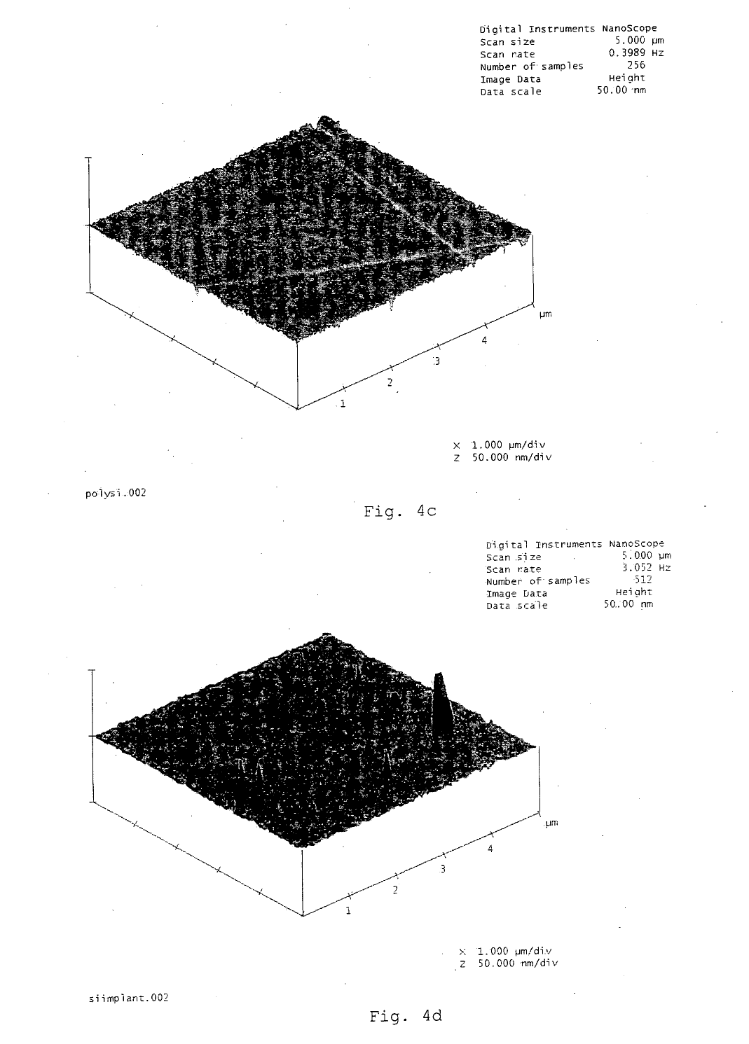

The UV-vis spectra of a bare glass substrate together with those modified by the deposition of amorphous silicon and implanted silicon ions are shown in FIG. 2. It can be seen from FIG. 2 that the UV-vis spectrum of the sample with implanted silicon ions is the same as that of bare glass, while the UV-vis spectrum of the sample with amorphous silicon coating is shifted to a higher wavelength (or infrared region), probably due to the absorption of the amorphous silicon film.

### Example 1.3

### Implantation of Non-Silicon Ions into a Substrate

Instead of implanting silicon, non-silicon ions at the same dosage of 1 E¹⁴/cm² were implanted into a glass substrate. These non-silicon ions include arsenic, boron and argon. The equipment used to implant the non-silicon ions into the glass wafers was the Varian ion implanter, using AsH₃, BH₃ and Ar as the respective ion source to implant arsenic, boron and argon ions respectively.

It is believed that as the implanted ions strike the surface, the ions damage the surface lattice and break some of the Si—O bonds of the SiO₂ molecules present in the glass surface. Hence, oxygen will escape from the glass surface, leaving silicon atoms on the glass surface and forming a silicon-rich glass surface. The depth of the silicon-rich glass surface is less than 10 nanometers.

### Example 1.4

### Argon Ion Sputtering of the Surface of a Substrate

The surface of a glass substrate was modified by argon ions sputtering. An argon ion source attached to an XPS machine was used for surface modification of the glass substrate. The argon ion dosage for sputtering was 1 E¹⁵/cm² where the energy for sputtering was set at 3 keV. The sputtering conditions such as ion energy and dosage can be changed accordingly.

This approach is similar to the approach used in Example 1.3, because during argon ion bombardment, the Si—O bonds of the SiO₂ molecules present in the glass surface were broken to form silicon atoms and oxygen atoms. As a result, more silicon atoms were then left on the glass surface after the oxygen atoms were removed via by this preferential sputtering method.

### Example 1.5

### Analysis of Modified Glass Substrates

Optical transmission and surface roughness of the modified glass substrates obtained from each of Examples 1.1 to 1.4 were tested here.

### Optical Transmission

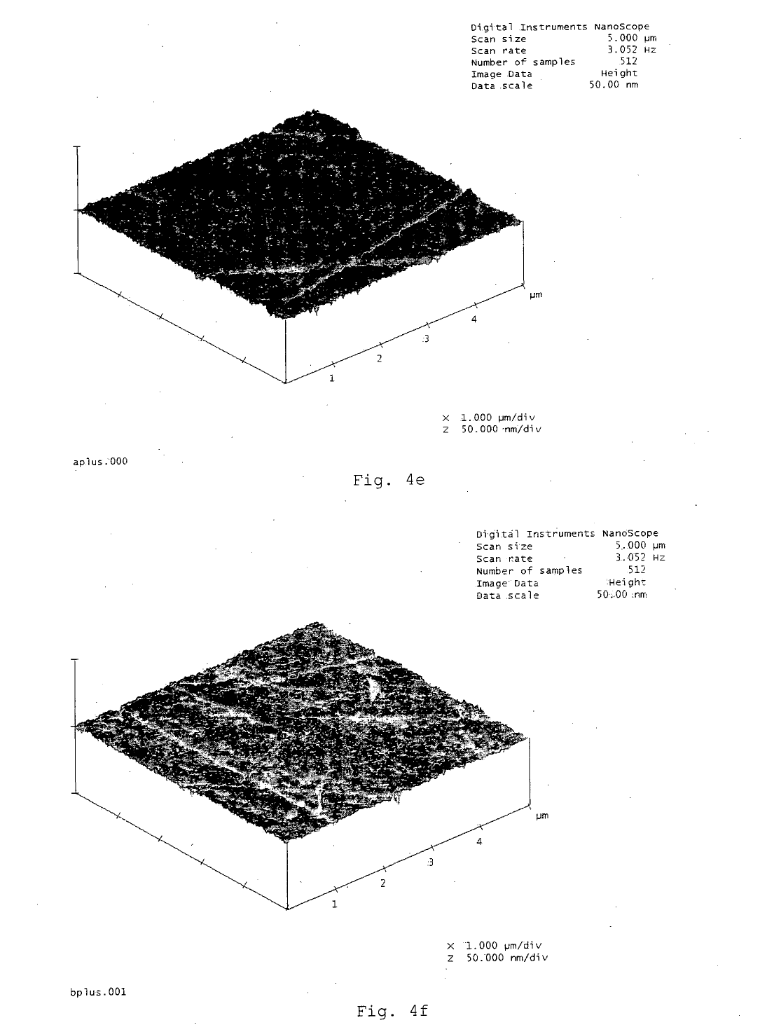

An Ocean Optics USD2000-UV-VIS optical fibre spectrometer was used to measure the optical spectra of the modified glass substrates. The wavelength range of the spectrometer was set between 200 nm to about 850 nm. Each sample was measured twice after calibrating the spectrometer. The results of this optical transmission test are shown in FIG. 3.

It can be seen from FIG. 3 that the optical transmission spectra of the glass substrate deposited on both sides with 30 nm amorphous silicon and of the glass substrate deposited on one side with 100 nm amorphous silicon were similar to the trend of the optical spectra of FIG. 1c and FIG. 1d respectively. The optical transparency of the glass substrate obtained from Example 1.4 (when argon was sputtered in XPS at 1 keV for 45 minutes) decreased when compared to that of the glass substrate obtained from Example 1.2, or from 93% to 77%. Further, FIG. 3 shows that glass substrates that had been implanted with silicon or non-silicon ions did not suffer from optical loss. Since there is no separate silicon (or non-silicon) layer on the surface of the glass substrates, optical reflection at the interface of the silicon (or non-silicon) and glass is absent, resulting in minimal optical loss when silicon (or non-silicon) are implanted into the glass substrate surface.

### Surface Roughness Measurement

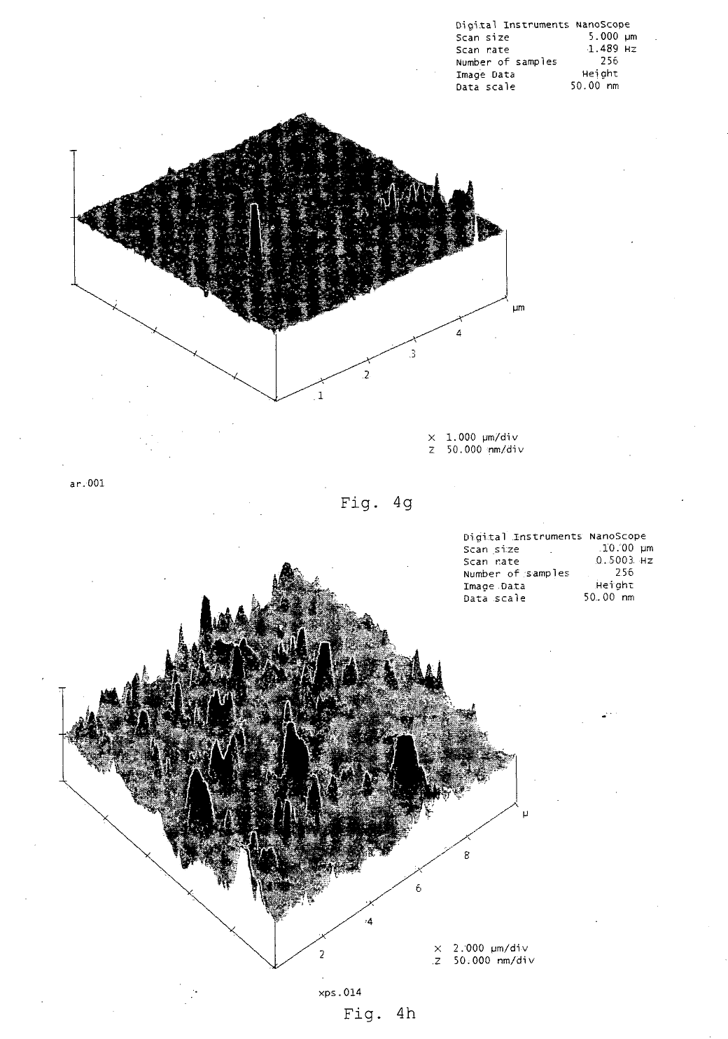

The surfaces of the glass substrates modified from Examples 1.1 to 1.4 were measured using an atomic force microscope (AFM) to check the roughness. It is desired that the surface modification do not roughen the glass surfaces. The results obtained from the AFM are shown in FIG. 4a to FIG. 4h. FIG. 4a is the AFM image of unmodified glass substrate. FIG. 4b is the AFM image of a glass substrate coated on one side with amorphous silicon of 100 nm thickness (or from Example 1.1). FIG. 4c is the AFM image of a glass substrate coated on both sides with amorphous silicon of 30 nm thickness (or from Example 1.1). FIG. 4d is the AFM image of a glass substrate modified via silicon ion implantation (or from Example 1.2). FIG. 4e is the AFM image of a glass substrate modified via arsenic ion implantation (or from Example 1.3). FIG. 4f is the AFM image of a glass substrate modified via boron ion implantation (or from Example 1.3). FIG. 4g is the AFM image of a glass substrate modified via argon ion implantation (or from Example 1.3). FIG. 4h is the AFM image of a glass substrate modified by argon sputtering in XPS (or from Example 1.4). FIG. 4a to FIG. 4g were scanned in an area of 5 μm×5 μm while FIG. 4h was scanned in an area of 10 μm×10 μm. The vertical scale of these images was fixed at 50 nm.

The Ra (surface roughness) values for the glass substrates in FIG. 4a to FIG. 4h were 0.966, 0.610, 0.905, 0.820, 1.092, 1.065, 1.332 and 8.342 nm, respectively.

Amorphous silicon deposition (FIG. 4b and FIG. 4c) actually smoothes the surface of the glass substrate, while silicon (FIG. 4c), arsenic (FIG. 4d), argon (FIG. 4e) or boron (FIG. 4f) ion implantation does not add any surface roughness within the range of measurement error. However, by using argon sputtering in a XPS machine, this method roughens the surface of the glass substrate (FIG. 4h), making it 9 times worse than its original flatness (FIG. 4a). Hence, the XPS argon sputtered glass substrate sample scattered some light and exhibited the transparency reduction shown in FIG. 3.

### Example 2

### Dispersion of Nanospheres on Substrate

Each of the modified glass substrate obtained from Examples 1.1 to 1.4 was cleaned by sonication in acetone for about 3 minutes, washed with deionized (DI) water and dried by nitrogen gas.

The glass substrates were then coated with a polyelectrolyte such as poly(diallyldimethylammonium chloride) (PDDA) (obtained from Sigma-Aldrich of St. Louis of Missouri of the United States of America) by dip-coating the substrate into a 1:5 diluted PDDA solution for about 30 seconds to electrostatically charge the surface. Following which, the glass substrates were washed with DI water and dried using nitrogen gas.

The nanospheres were received as a 10% suspension in water, and had been diluted with DI water at a ratio between 1:10 and 1:100. Polystyrene nanospheres having diameters of 170 nm, 260 nm and 360 nm and silicon nanospheres having a diameter of 500 nm were used. The polystyrene nanospheres and silicon nanospheres were obtained from Duke Scientific Corporation of Fremont of California of the United States of America. About 1 ml of the diluted nanosphere solution was drop-coated onto each of the glass substrates. After drop-coating, the glass substrates were rinsed by DI water to get rid of excessive nanospheres. As the DI water evaporated, capillary force tended to draw the nanospheres together. However, the electrostatic interaction between the nanospheres impeded this close-packed arrangement and dispersed nanospheres were obtained on the surface of the substrate.

### Surface Electron Microscope (SEM)

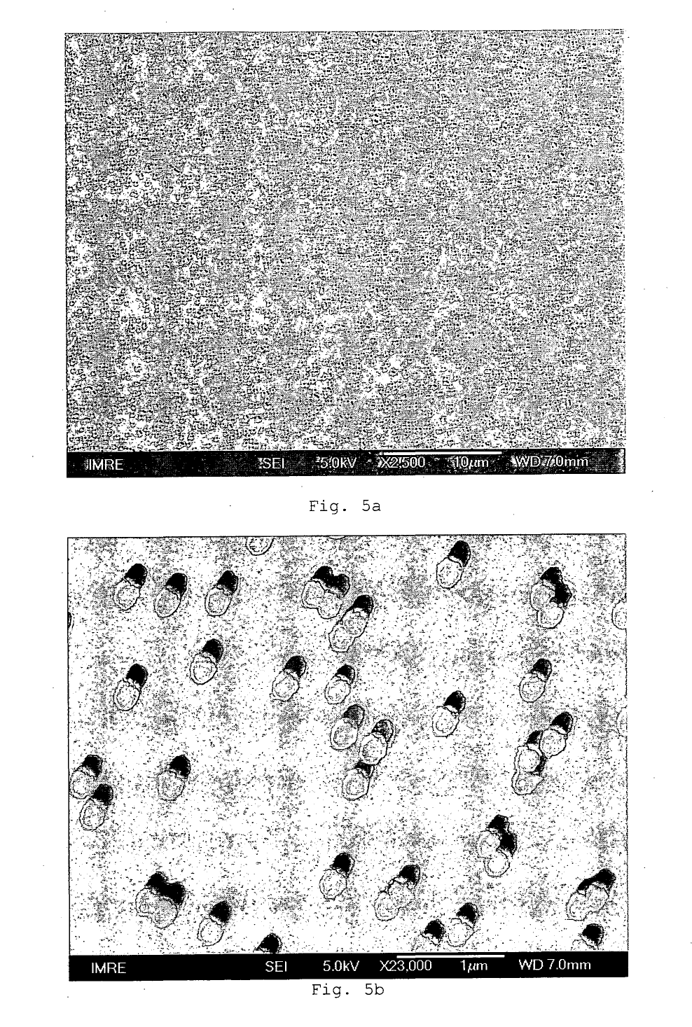

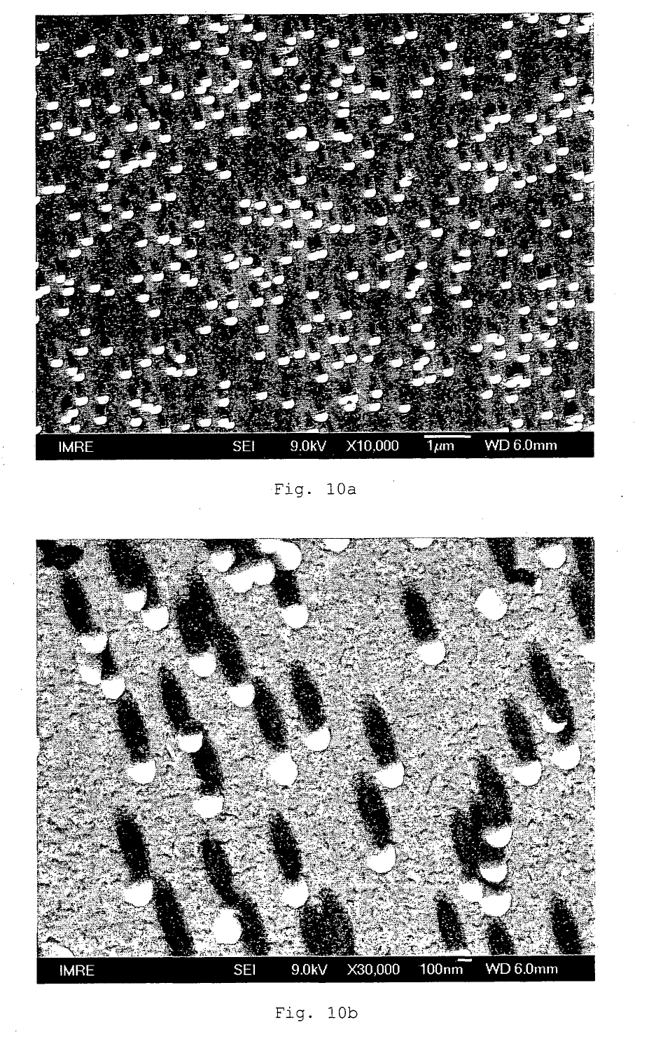

The SEM images of the modified glass substrates coated with the nanospheres are shown in FIGS. 5a, 5b, 6a, 6b, 7a to 7d, 8a to 8d, 9a, 9b, 10a and 10b. As a control, the SEM images of an unmodified glass substrate without PDDA treatment are shown in FIG. 11a and 11b.

FIG. 5a is a SEM image obtained at 2500× magnification of the nanospheres dispersed on both sides of a glass substrate with amorphous silicon deposition (to a thickness of 30 nm) followed by PDDA treatment. FIG. 5b is the magnified image of FIG. 5a, obtained at 23000× magnification. It can be seen from FIG. 5a and FIG. 5b that the nanospheres were dispersed over a large area, that the nanospheres do not substantially clump together, that the nanospheres are uniformly dispersed and hence, this fulfills the requirements for narrow-peak LSPR excitations.

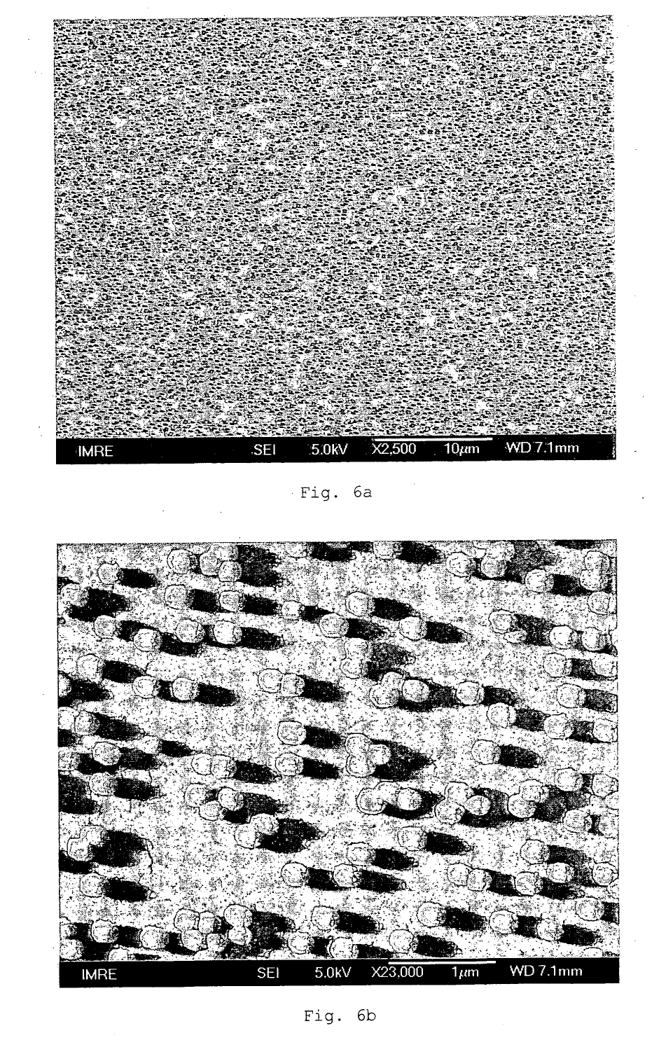

FIG. 6a is a SEM image obtained at 2500× magnification of the nanospheres dispersed on a glass substrate implanted with silicon ions at a dosage of 1 E¹⁴/cm² followed by PDDA treatment. FIG. 6b is the magnified image of FIG. 6a, obtained at 23000× magnification. It can be seen from FIG. 6a and FIG. 6b that the dispersion of the nanospheres over a large area is as good as that obtained via silicon deposition. This was also observed by the naked eye as a uniform white colour on the glass substrate when the nanospheres are well-dispersed. If the substrate was not well-coated, some areas on the substrate will appear to be very white with some areas blank.

From the results obtained using silicon deposition and implantation, it can be observed that the nanospheres can be well-dispersed as long as the glass substrate is modified such that it possesses the surface charge property of silicon. It was also noted that all of the silicon modified glass substrates have reduced electrical charges under SEM, indicating that the glass substrate became more conductive after surface modification.

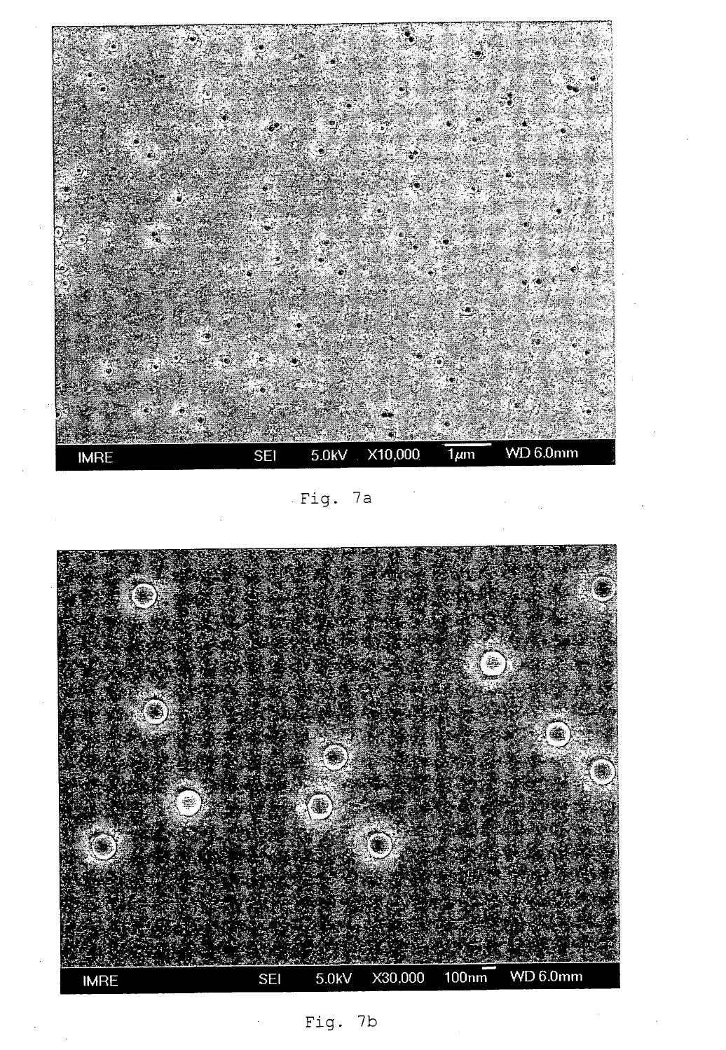

FIG. 7a is a SEM image obtained at 10,000× magnification of the nanospheres dispersed on a glass substrate implanted with arsenic ions at a dosage of 1 E¹⁴/cm² followed by PDDA treatment. FIG. 7b is the magnified image of FIG. 7a, obtained at 30,000× magnification. FIG. 7c is another SEM image obtained at 5,000× magnification of the nanospheres dispersed on a glass substrate implanted with arsenic ions followed by PDDA treatment. FIG. 7d is the magnified image of FIG. 7c, obtained at 10,000× magnification. FIG. 7a was the SEM image taken before a layer of gold was evaporated thereon, while the SEM image shown in FIG. 7c was taken after 50 nm of gold had been evaporated at an angle of 70° onto the nanospheres dispersed on the modified glass substrate. The function of the gold layer is to reduce the electrical charge in SEM in order to provide a clearer SEM image.

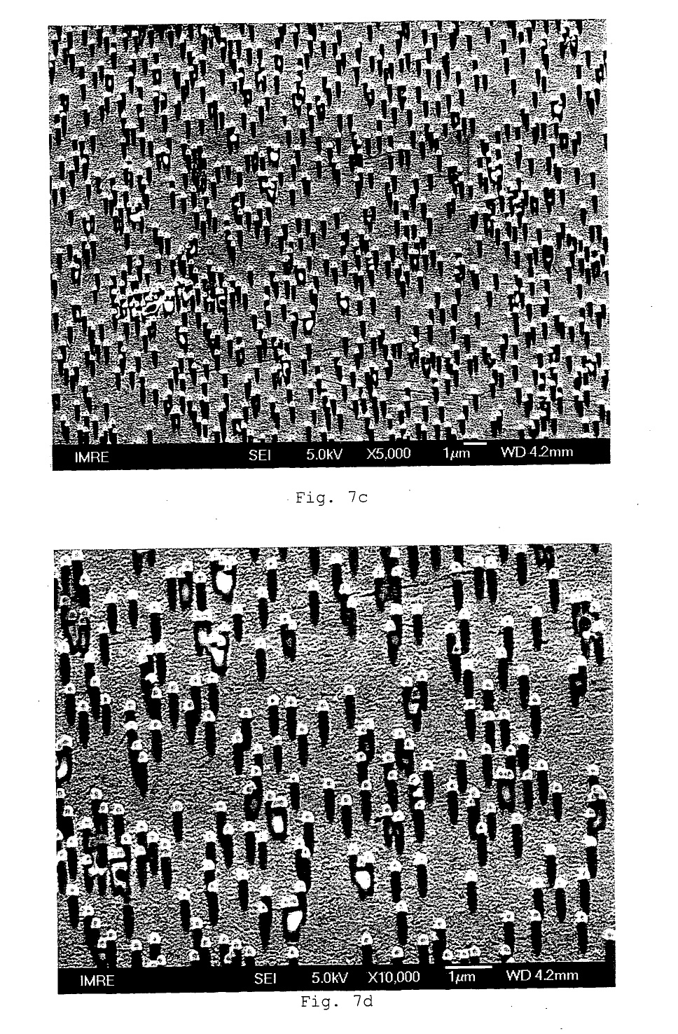

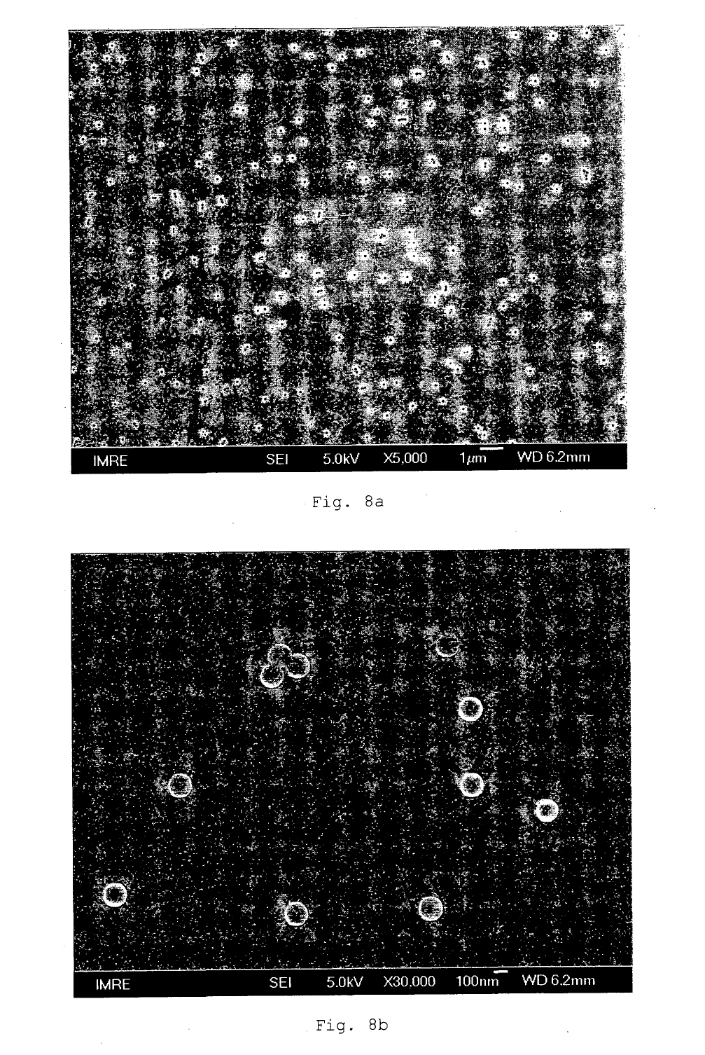

FIG. 8a is a SEM image obtained at 5,000× magnification of the nanospheres dispersed on a glass substrate implanted with boron ions at a dosage of 1 E¹⁴/cm² followed by PDDA treatment. FIG. 8b is the magnified image of FIG. 8a, obtained at 30,000× magnification. FIG. 8c is another SEM image obtained at 3,000× magnification of the nanospheres dispersed on a glass substrate implanted with boron ions followed by PDDA treatment. FIG. 8d is the magnified image of FIG. 8c, obtained at 10,000× magnification. The SEM image shown in FIG. 8a was obtained without evaporating gold thereon, while the SEM image shown in FIG. 8c was taken after 50 nm of gold was evaporated at an angle of 70° onto the dispersed nanospheres.

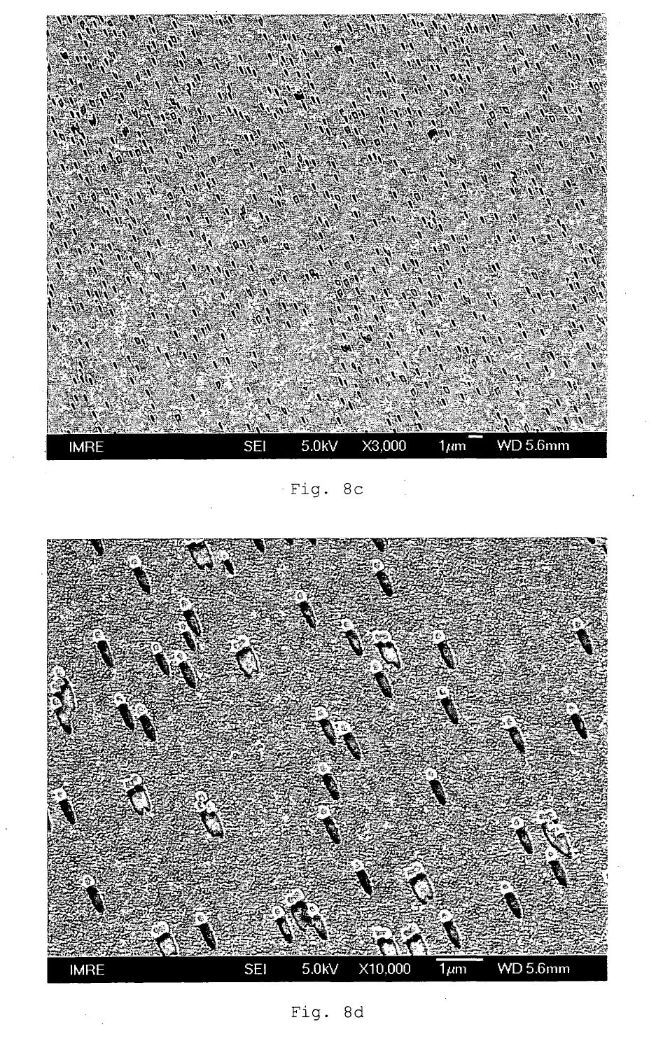

FIG. 9a is a SEM image obtained at 10,000× magnification of the nanospheres dispersed on a glass substrate implanted with argon ions at a dosage of 1 E¹⁴/cm² followed by PDDA treatment. FIG. 9b is the magnified image of FIG. 9a, obtained at 30,000× magnification.

The results obtained using non-silicon implantation showed that the dispersion of nanospheres on the glass substrate was not as good as silicon ion implantation. This is because silicon ions implantation can result in more silicon atoms being present in the glass surface.

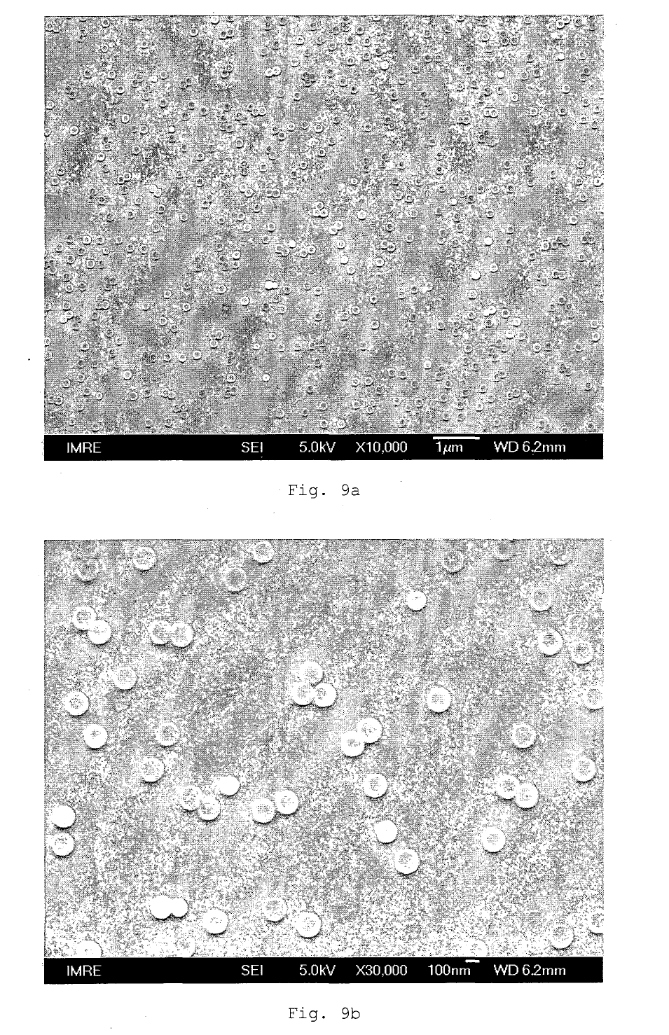

FIG. 10a is a SEM image obtained at 10,000× magnification of the nanospheres dispersed on a glass substrate sputtered with argon ions at a dosage of 1 E¹⁵/cm² in a XPS machine with sputtered energy of 3 keV for 90 minutes followed by PDDA treatment. FIG. 10b is the magnified image of FIG. 10a, obtained at 30,000× magnification. These figures show that the nanospheres were well-dispersed on the glass substrate.

### Example 3

### Deposition of Gold on Nanospheres

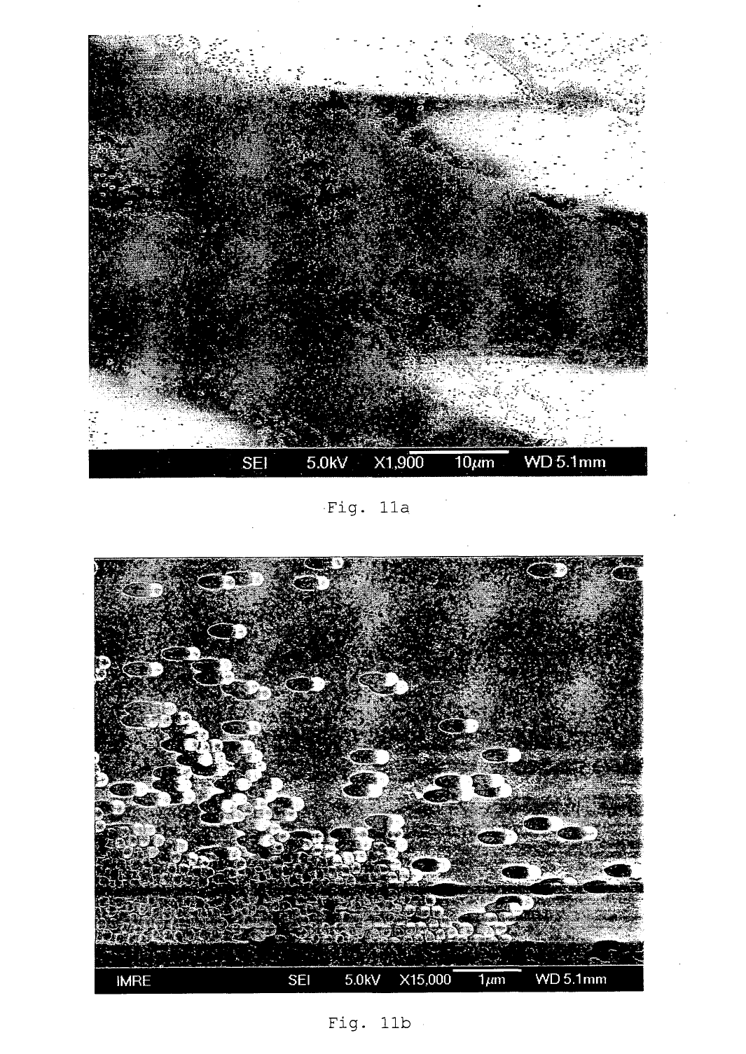

The glass substrate obtained from Example 1.2 (silicon implantation) was treated with PDDA and coated with polystyrene nanospheres having a diameter of 170 nm following the steps of Example 2. After the nanospheres were dispersed onto the modified, PDDA treated glass substrates, 30 nm of gold was thermally evaporated on the nanospheres at an angle of 70° by a R-Dec thermal evaporator at a rate of 0.5-0.7 Å/s. Following which, the LSPR spectra of the nanostructures were measured using an Ocean Optics spectrometer. When taking the measurement, the gold layer was not etched and the nanospheres were not removed, because the gold deposited on each nanosphere can be used as the gold nanostructure of LSPR. The LSPR spectra of the gold nanostructures are shown in FIG. 12. FIG. 12 was measured in various media such as air, water and 50 wt % glocyrol, which have refractive indices of 1, 1.33 and 1.40, respectively. FIG. 12 indicates that these gold nanostructures have a LSPR sensitivity of 182 nm/RIU. This sensitivity is critical for SPR sensor chip application.

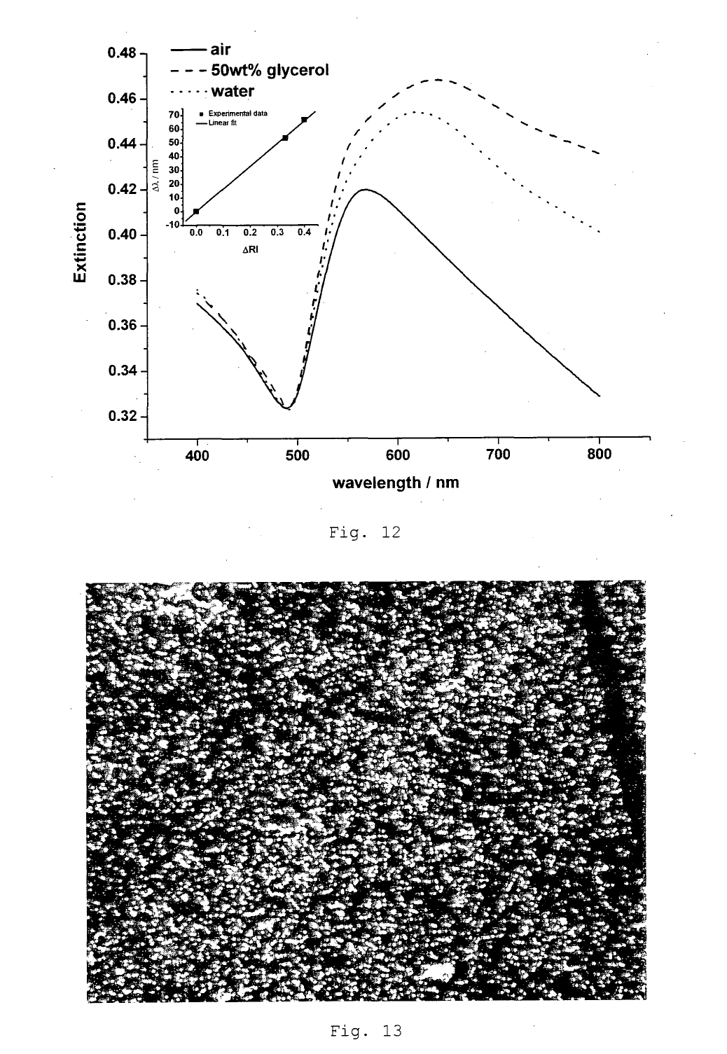

A second sample was fabricated and visualized using a dark-field microscope to determine LSPR emission. The glass substrate obtained from Example 1.2 was treated with PDDA and coated with polystyrene nanospheres having a diameter of 170 nm following the steps of Example 2. After the nanospheres were dispersed onto the modified, PDDA treated glass substrates, 50 nm of gold was thermally evaporated on the nanospheres at an angle of 70°. The gold film was etched by inductively coupled plasma (ICP). Although the nanospheres were not removed, the gold nanocrescents under the nanospheres on the glass substrate were acting as gold nanostructures for LSPR. The LSPR emission of the gold nanostructures was then visualized using a dark-field microscope, as seen in FIG. 13. In FIG. 13, each spot represents a plasmonics emission dot and it can be seen from FIG. 13 that the nanospheres dispersed well over a large area on the glass substrate.

### Example 4

### Effect of Substrate on Dispersion

In order to determine the possibility of using other materials as the substrate instead of a glass substrate, four materials were tested to see if nanospheres can be dispersed on them with and without PDDA treatment.

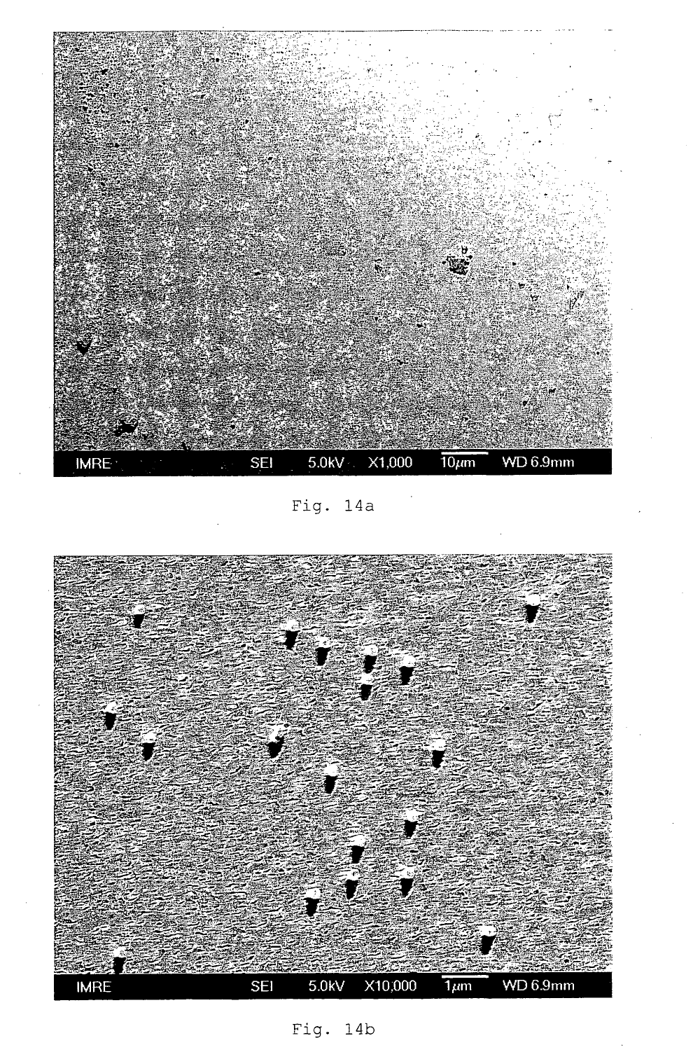

The four surfaces tested were silica (SiO₂), titanium (Ti), poly(dimethylsiloxane) (PDMS) and poly(methyl methacrylate) (PMMA). The silica substrate was obtained by growing a pure silica layer on a silicon substrate using an oxidation furnace at 1000° C.; the, titanium layer was obtained by evaporating a layer of titanium using a thermal evaporator; the PDMS layer was obtained by spinning PDMS on a glass substrate; and the PMMA layer was commercially available. The nanosphere dispersion experiments were carried out as described in Example 3. According to the nanosphere dispersion experiments performed, without PDDA treatment, only SiO₂ can poorly disperse some nanospheres in some areas. The SEM images of this experiment are shown in FIG. 14a (under 1000× magnification) and FIG. 14b (under 10,000× magnification). These figures show that the dispersion on the SiO₂ surface without PDDA treatment was similar to that of an unmodified glass surface without PDDA treatment (FIG. 11a).

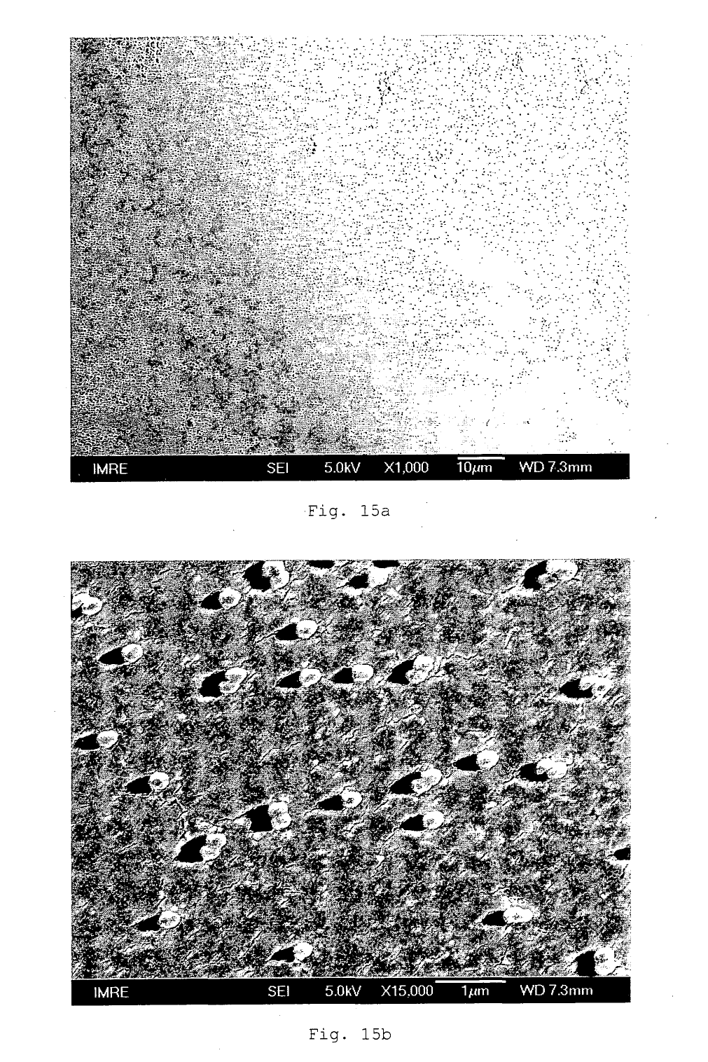

With PDDA treatment, the PDMS surface was still not able to retain and disperse the nanospheres. This could be due to the highly hydrophobic nature of the PDMS. The results of the other surfaces are presented in FIGS. 15a, 15b, 16a, 16b, 17a and 17b.

FIG. 15a is a SEM image obtained at 1,000× magnification of nanospheres dispersed on a PMMA plastic plate treated with PDDA. FIG. 15b is the magnified image of FIG. 15a obtained at 15,000× magnification.

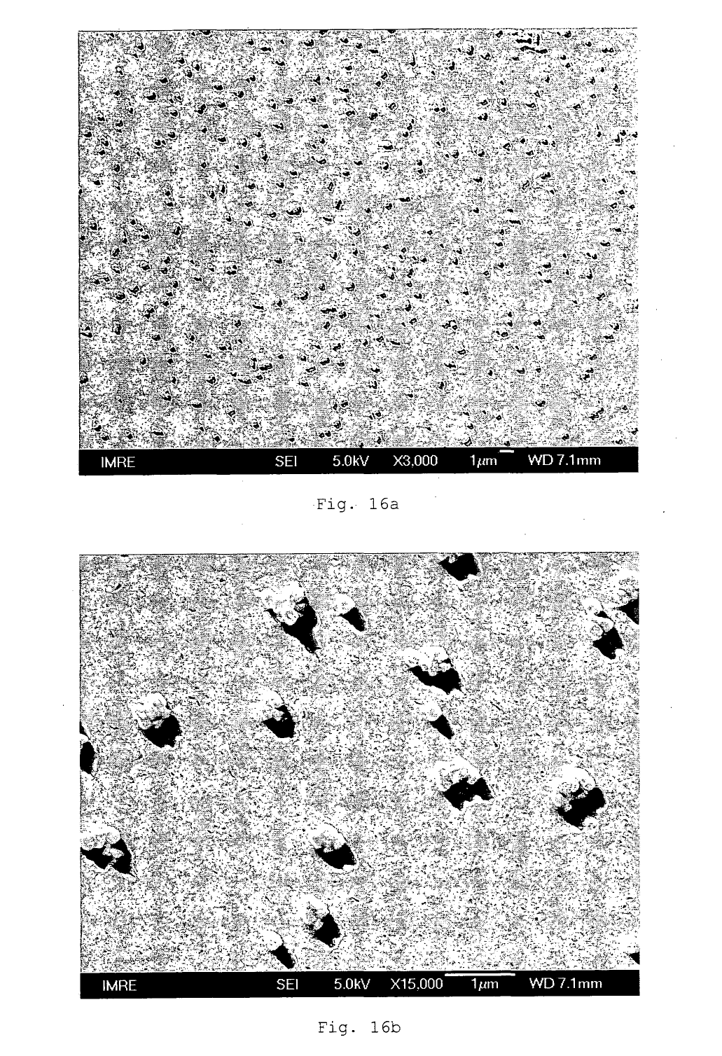

FIG. 16a is a SEM image obtained at 3,000× magnification of nanospheres dispersed on a SiO₂ surface treated with PDDA. FIG. 16b is the magnified image of FIG. 16a obtained at 15,000× magnification.

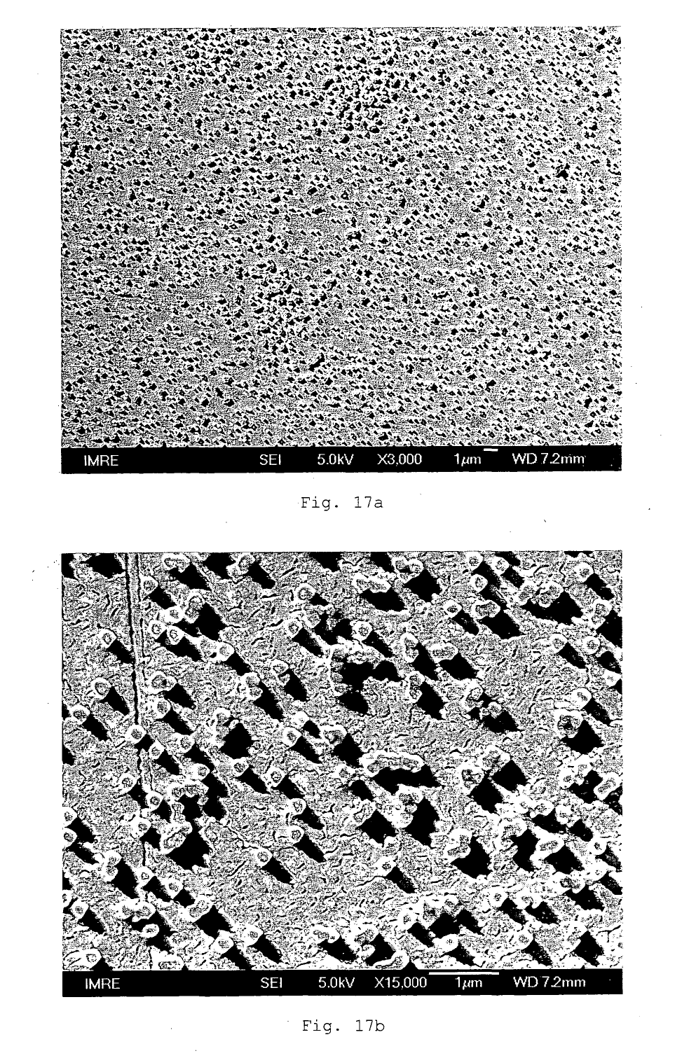

FIG. 17a is a SEM image obtained at 3,000× magnification of nanospheres dispersed on a titanium surface treated with PDDA. FIG. 17b is the magnified image of FIG. 17a obtained at 15,000× magnification.

The results obtained showed that the PMMA substrate had better dispersion results compared to that of SiO₂ and titanium surfaces. It can be seen that the nanospheres on the SiO₂ and titanium surfaces randomly congregate into small nanosphere groups. However, these results are not comparable to the results obtained in Example 2 and are not good enough for LSPR applications.

Further, in PMMA patterning method, the nanospheres can only be removed by tape-stripping, which is in contrast to the present method whereby the nanospheres can be removed massively and effectively by sonicating the samples in toluene or ethanol. Hence, this limits the area size and efficiency of fabricating the nanospheres. Commercially available PMMA plastic plates are not suitable to replace glass substrates as they are too thick (around 2 mm thick) with poor transparency.

### Example 5

### Effect of Concentration of Nanospheres on Dispersion

To determine whether the concentration of nanospheres is a factor in the dispersion on the modified PDDA treated glass substrates, experiments were carried out by varying the dilution ratio of the polystyrene nanospheres having a diameter of 170 nm. These dilution ratios are 1:15, 1:30, 1:50, 1:70 and 1:100. The SEM images of the dispersed nanospheres on the glass substrates for each dilution ratio were obtained. From the SEM images, it was observed that the densities of the nanospheres dispersed on the glass substrate for each dilution ratio remained the same. It was postulated that PDDA provided a specific force to the nanospheres, and dispersed the nanospheres on the glass substrate at a relevant density of 3 nanospheres/μm², which was independent of the original concentration of the nanospheres.

### Applications

The disclosed method of modifying a substrate for deposition of charged particles thereon is an efficient yet simple method for preparing a substrate that is capable of having charged particles substantially evenly distributed throughout its surface. Advantageously, the substrate prepared by the disclosed method can be used to disperse nanoparticles substantially evenly throughout its surface. More advantageously, there is little or no aggregation and congregation of particles in specific areas on the substrate that is prepared by the disclosed methods. Accordingly, utilization of the entire surface area of the substrate is maximized.

As the prepared substrate would have an electrical polarity/charge that is opposite to that of the particles to be dispersed, the electrostatic forces ensures that the particles are securely adhered to the surfaces while at the same time be relatively evenly spread out. Advantageously, this ensures that substrates containing a desired density of dispersed particles are easily and consistently reproducible. Hence, the desired density of particles on the substrate can be controlled according to the users' requirements. This is especially advantageous when the substrates are used in several experiments, all of which requiring the density of distributed particles to be fixed.

Since the disclosed method can produce optically transparent substrates which have evenly distributed nanoparticles thereon, nanostructures can be subsequently formed on the substrate by utilizing the exposed area surrounding the nanoparticles. The resulting optically transparent substrate containing the nanostructures can then be advantageously used for LSPR applications.

As the present method is an efficient and simple method, the present method can be used to fabricate nanostructures on a suitable substrate in a cost effective manner.

While reasonable efforts have been employed to describe equivalent embodiments of the present invention, it will be apparent to the person skilled in the art after reading the foregoing disclosure, that various other modifications and adaptations of the invention may be made therein without departing from the spirit and scope of the invention and it is intended that all such modifications and adaptations come within the scope of the appended claims.

1. A method of modifying a substrate for deposition of charged particles thereon, the method comprising the steps of:
providing a substrate that is incapable of readily adhering to a polyelectrolyte coating that has a charge that is opposite to the charge of the particles that are to be deposited thereon;
modifying the surface of the substrate to provide a layer of silicon thereon or therein; and
coating the silicon layered surface of the substrate with the polyelectrolyte coating, the polyelectrolyte coating containing functional groups that are capable of forming bonds with said silicon layer and wherein said polyelectrolyte coating enables a substantially even distribution of said charged particles to be deposited thereon.

2. A method as claimed in claim 1, wherein said polyelectrolyte is a polycation.

3. A method as claimed in claim 2, wherein said polycation comprises at least one of quaternary ammonium groups and amino groups.

4. A method as claimed in claim 3, wherein said quaternary ammonium groups and amino groups of said polyelectrolyte coating are selected from the group consisting of a linear or branched poly(ethylene imine) (PEI), poly (allylamine hydrochloride) (PAH), poly(diallyldimethylammonium chloride) (PDDA), polyvinyl pyridine (PVP), polylysine and precursors thereof.

5. A method as claimed in claim 1, wherein said charged particles are nano-sized or micro-sized particles.

6. A method as claimed in claim 5, wherein said charged nano-sized or micro-sized particles are comprised of a material selected from the group consisting of polystyrene, latex, silica and quartz.

7. A method as claimed in claim 1, wherein said silicon layer is a nano-layer.

8-27. (canceled)

28. A method as claimed in claim 7, wherein said silicon nano-layer is integral with the substrate and is disposed adjacent to the surface of the substrate.

29. A method as claimed in claim 28, wherein the modifying step comprises the step of implanting silicon ions into the substrate.

30. A method as claimed in claim 28, wherein the substrate comprise silicon-containing compounds and wherein the modifying step comprises the step of implanting non-silicon ions into the substrate to release silicon atoms from the silicon-containing compounds within the substrate.

31. The method as claimed in claim 28, wherein the substrate comprise silicon-containing compounds and wherein the modifying step comprises the step of depositing non-silicon ions onto the surface of the substrate to release silicon atoms from the silicon-containing compounds in the substrate.

32. The method as claimed in claim 31, wherein the silicon ions or non-silicon ions used are at a dosage in the range from IE1 VCm² to IE16/cm².

33. A method as claimed in claim 7, wherein said silicon nano-layer is a discrete layer disposed on the surface of the substrate.

34. A method as claimed in claim 1, wherein the modifying step comprises the step of depositing silicon atoms onto the surface of the substrate.

35. A method as claimed in claim 34, wherein said depositing silicon atoms onto the surface of the substrate step comprises the step of depositing silicon atoms using a chemical vapor deposition method.

36. The method as claimed in claim 34, wherein said depositing silicon atoms onto the surface of the substrate comprises the step of depositing silicon atoms using a sputtering method.

37. The method as claimed in claim 36, wherein the silicon ions or non-silicon ions used are at a dosage in the range from IE1 VCm² to IE16/cm².

38. The method as claimed in claim 1, wherein said particles are capable of being dispersed onto the substrate such that the dispersed particles are substantially evenly distributed over at least 80% of the area of said surface.

39. The method as claimed in claim 1, wherein the substrate is optically transparent.

40. The method as claimed in claim 39, wherein the optically transparent substrate has a light transmission of from 70% to 100%.

41. A method of depositing charged particles on a substrate, the method comprising the steps of:
providing a substrate that is incapable of readily adhering to a polyelectrolyte coating that has a charge that is opposite to the charge of the particles that are to be deposited thereon;
modifying the surface of the substrate to provide a layer of silicon thereon or therein; coating the silicon layered surface of the substrate with the polyelectrolyte coating, the polyelectrolyte coating containing functional groups that are capable of forming bonds with said silicon layer; and depositing a suspension of the charged particles over the coated surface, wherein said polyelectrolyte coating enables a substantially even distribution of said charged particles deposited thereon.

42. The method as claimed in claim 41, wherein the density of dispersed particles on the surface is independent of the concentration of particles in the suspension for a fixed total number of particles.

43. A method of forming nano-particles on a substrate capable for Localized Surface Plasmon Resonance, the method comprising:
providing a substrate that is incapable of readily adhering to a polyelectrolyte coating; modifying the surface of the substrate to provide a layer of silicon thereon or therein;
coating the silicon layered surface of the substrate with the polyelectrolyte coating, the polyelectrolyte coating containing functional groups that are capable of forming bonds with said silicon layer and wherein said polyelectrolyte coating enables a substantially even distribution of said charged particles deposited thereon;
depositing a suspension of charged particles over the coated surface, said particles having a charge that is opposite to the charge of the polyelectrolyte coating;
depositing noble metals on said particle-containing surface; and etching the deposited noble metals to form nanostructures on said substrate.

44. A substrate that is incapable of readily adhering to a polyelectrolyte coating comprising:
a layer of silicon on or within said substrate that has bonded with functional groups within the polyelectrolyte coating; and
charged particles substantially evenly distributed on said substrate.

45. The substrate as claimed in claim 44, wherein the charged particles are nanostructures.

46. The substrate as claimed in claim 45, wherein the nanostructures are coated with a metal coating thereon.

47. A localized surface plasmon resonance system comprising: a source of light;
a sensor chip comprising a substrate having a layer of silicon on or within said substrate that has bonded with functional groups within a polyelectrolyte coating and nano-sized reflective particles substantially evenly distributed on said substrate, said nano-sized reflective particles being disposed along an optical path for the transmission of a light beam from the light source to produce a localized surface plasmon resonance signal; and a detector disposed along the optical path for detecting the localized surface plasmon resonance signal emitted by said reflective particles.
